(19) United States
(12) Patent Application Publication
(10) Pub. No.: US 2012/0132991 A1
(43) Pub. Date: May 31, 2012

(54) ORGANIC THIN-FILM TRANSISTOR, AND PROCESS FOR PRODUCTION THEREOF

(75) Inventors: Yasutaka Kuzumoto, Osaka (JP); Shigeru Aomori, Osaka (JP); Masakazu Kamura, Osaka (JP)

(73) Assignee: SHARP KABUSHIKI KAISHA, Osaka-shi ,Osaka (JP)

(21) Appl. No.: 13/389,235

(22) PCT Filed: Sep. 2, 2010
(86) PCT No.: PCT/JP2010/065044

§ 371 Date: Feb. 6, 2012

(30) Foreign Application Priority Data
Nov. 25, 2009 (JP) 2009-267854

(51) Int. Cl. H01L 51/10; H01L 51/40

(52) U.S. Cl. 257/347; 438/158; 438/99; 257/40; 257/E51.003

(57) ABSTRACT

An organic thin-film transistor (100) includes, on a substrate (1), a gate electrode (2), a gate insulating layer (3), a source electrode (4), and a drain electrode (5). Part of surface of the source electrode (4) is covered by a first organic molecular layer (6a). Part of surface of the drain electrode (5) is covered by a second organic molecular layer (6b). An organic semiconductor layer (7) is formed so as to cover the organic molecular layer (6) (first and second organic molecular layers (6a, 6b)), the source electrode (4), and the drain electrode (5), and get into a channel section (20) which is a gap between the electrodes. Since the organic thin-film transistor (100) has the organic molecular layer (6) covering at least part of surface of each of the source and drain electrodes (4, 5), hole-electron injection efficiency is increased. This makes it possible to obtain large current.

### TECHNICAL FIELD

The present invention relates to an organic thin-film transistor whose semiconductor part is made from an organic material, and to a method for manufacturing the organic thin-film transistor.

### BACKGROUND ART

Recently, display apparatuses are under active development. Particularly, widely prevalent are flat panel displays (FPD) with thin thicknesses. In the case of the FPDs, it is common to employ thin-film transistors in pixel-by-pixel switching control or in drive control of the display apparatuses. Recently, however, there is an increasing expectation for utilizing organic thin-film transistors instead of the thin-film transistors. The organic thin-film transistors are three-terminal active elements which utilize an electrical property of a semiconductor. The organic thin-film transistors are utilized in a wide range of fields, as switching elements, control circuits, or the like of display apparatuses. Particularly, the organic thin-film transistors are utilized in display apparatuses such as liquid crystal display apparatuses and organic electroluminescence (EL) display apparatuses. Recently, also expected is application of the organic thin-film transistors to integrated-circuit technologies for electronic devices such as electronic papers, sheet displays, and biosensors.

An organic thin-film transistor has, on its substrate, at least an organic semiconductor layer, a gate electrode, a source electrode, a drain electrode, and a gate insulating layer. Specifically, the organic thin-film transistor has the gate electrode on the substrate. The gate insulating layer is formed so as to cover the gate electrode. The source electrode and the drain electrode are provided on the gate insulating layer so as to have a space therebetween. Further, the organic semiconductor layer is formed so as to cover the source electrode and the drain electrode and so as to also intervene therebetween. Such a structure that the source electrode and the drain electrode are formed under the organic semiconductor layer is referred to as bottom contact structure. Similarly, a structure in which the source electrode and the drain electrode are formed on the organic semiconductor layer is referred to as top contact structure.

It is known that a crystal grain size of an organic semiconductor layer in an organic thin-film transistor is affected by a status of a surface with which the organic semiconductor layer has contact (Non-patent Literature 1). For example, as illustrated in FIG. 15, an organic thin-film transistor 30a having the bottom contact structure is arranged such that an organic semiconductor layer 7 is formed directly on the source electrode 4 and the drain electrode 5. By being provided on the source electrode 4 and the drain electrode 5, the organic semiconductor layer 7 is accordingly made smaller in crystal grain size. FIG. 15 is a cross-sectional view of the organic thin-film transistor 30a having the bottom contact structure. As illustrated in FIG. 15, the organic semiconductor layer 7 partially has a direct contact with each of the source electrode 4 and the drain electrode 5. In such parts of the organic semiconductor layer 7, crystals 18 are small in grain size. This is because the crystals 18 are affected by high surface energy of the source electrode 4 and the drain electrode 5. On the other hand, the organic semiconductor layer 7 is larger in crystal grain size in its part which does not have a direct contact with the source electrode 4 nor with the drain electrode 5. Thus, the organic semiconductor layer 7 is smaller in crystal grain size in the vicinity of the source electrode 4 and the drain electrode 5 in that organic thin-film transistor 30a having the bottom contact structure in which the organic semiconductor layer 7 is formed directly on the source electrode 4 and the drain electrode 5. The reduction in crystal grain size of organic semiconductor layer 7 decreases carrier injectability between the organic semiconductor layer 7 and each of the source electrode 4 and the drain electrode 5. This leads to a problem of a decrease in current which flows between the source electrode 4 and the drain electrode 5.

As a solution to the problem, as illustrated in FIG. 16, there is such a technique that an organic molecular layer 6 is provided between the organic semiconductor layer 7 and each of the source electrode 4 and the drain electrode 5. FIG. 16 is a cross-sectional view illustrating that organic thin-film transistor 30b having the bottom contact structure in which the organic molecular layer 6 is provided. As illustrated in FIG. 16, a first organic molecular layer 6a is provided between the source electrode 4 and the organic semiconductor layer 7, and a second organic molecular layer 6b is provided between the drain electrode 5 and the organic semiconductor layer 7. This makes it possible to form crystals 17 large in grain size in the vicinity of the organic molecular layer 6 (first organic molecular layer 6a and second organic molecular layer 6b). This is because the organic molecular layer 6 has a small surface energy, and accordingly, crystal grains in the organic semiconductor layer 7 grow large in size.

For example, Patent Literature 1 discloses an organic thin-film transistor which is arranged such that a molecular absorption layer made up of electron-donating organic molecules containing sulfur atoms is formed in respective surface regions of a source electrode and a drain electrode. According to the arrangement, an organic semiconductor layer has a uniform crystal grain size at an interface between the organic semiconductor layer and the source electrode or the drain electrode. In addition, adhesion is increased between the organic semiconductor layer and the source electrode or the drain electrode. This makes it possible to obtain an organic thin-film transistor with a low threshold voltage and a large on-state current.

Further, Patent Literature 2 discloses an organic thin-film transistor which is arranged such that a first organic molecular film is provided on a source electrode and a drain electrode, and a second organic molecular film is provided on a channel section. According to the arrangement, the first organic molecular film provided on the source electrode and the drain electrode is larger in crystal grain size. This makes it possible to reduce electrical contact resistance. As a result, it is possible to realize an organic thin-film transistor with higher performance.

### CITATION LIST

Patent Literatures

Patent Literature 1
Japanese Patent Application Publication, Tokukai, No. 2004-288836 A (Publication Date: Oct. 14, 2004)

Patent Literature 2
Japanese Patent Application Publication, Tokukai, No. 2007-158140 A (Publication Date: Jun. 21, 2007)

Non-Patent Literature

Non-Patent Literature 1
IEEE TRANSACTION ON ELECTRON DEVICES, VOL. 48, No. 6, pp. 1060, 2001

### SUMMARY OF INVENTION

### Technical Problem

The aforementioned method in which the organic molecular film is provided between the organic semiconductor layer, and the source and drain electrodes makes it possible to make the organic semiconductor layer larger in crystal grain size. However, in a case where the organic molecular film is provided between the organic semiconductor layer and the source and drain electrodes, carrier injection between the source electrode and the organic semiconductor layer, and carrier injection between the drain electrode and the organic semiconductor layer are performed via the organic molecular film. Accordingly, the organic molecular film serves as a resistance component. The following describes this in detail, with reference to FIG. 17. FIG. 17 is an enlarged view illustrating an organic semiconductor layer 7 of that organic thin-film transistor 30b of a bottom contact structure which has an organic molecular layer 6.

As illustrated in FIG. 17, crystals 17 are large in grain size in the vicinity of the organic molecular layer 6, due to an effect of the organic molecular layer 6. However, when a carrier is injected from the source electrode 4, the organic molecular layer 6 (first organic molecular layer 6a) serves as a resistance component. As a result, the carrier injection cannot be performed efficiently. The same holds for the drain electrode 5. Accordingly, carrier injectability is low. Therefore, it is impossible to obtain a sufficient current which is supposed to be obtained. Thus, according to the aforementioned method, it is impossible to obtain a sufficient current from the organic thin-film transistor nor improve the performance of thereof, although it is possible to make the organic semiconductor layer larger in crystal grain size.

The present invention was made in view of the problem. An object of the present invention is to provide (i) a high-performance organic thin-film transistor which achieves a large on-state current by preventing decrease in efficiency of carrier injection from an electrode which decrease is caused due to a decreased crystal grain size of an organic semiconductor layer, and (ii) a method for manufacturing the high-performance organic thin-film transistor.

### Solution to Problem

In order to attain the object, an organic thin-film transistor of the present invention includes: a substrate; a gate electrode being formed on said substrate; a gate insulating layer being formed on said gate electrode; a source electrode being formed on said gate insulating layer; a drain electrode being formed on said gate insulating layer so as to be spaced from said source electrode; a first organic molecular layer which, as a continuous layer, covers (i) a side surface of said source electrode which side surface faces said drain electrode, and (ii) a part of a top surface of said source electrode; a second organic molecular layer which, as a continuous layer, covers (i) a side surface of said drain electrode which side surface faces said source electrode, and (II) a part of a top surface of said drain electrode; and an organic semiconductor layer which, as a continuous layer, covers at least (i) a part of the top surface of said source electrode, (ii) a part of the top surface of said drain electrode, (iii) at least a part of a surface of said first organic molecular layer, (iv) at least a part of a surface of said second organic molecular layer, and (v) at least a part of a gap between said source electrode and said drain electrode.

In order to attain the object, an organic thin-film transistor of the present invention includes: a substrate; a source electrode being formed on said substrate; a drain electrode being formed on said substrate so as to be spaced from said source electrode; a first organic molecular layer which, as a continuous layer, covers (i) a side surface of said source electrode which side surface faces said drain electrode, and (ii) a part of a top surface of said source electrode; a second organic molecular layer which, as a continuous layer, covers (I) a side surface of said drain electrode which side surface faces said source electrode, and (II) a part of a top surface of said drain electrode; an organic semiconductor layer which, as a continuous layer, covers at least (i) a part of the top surface of said source electrode, (ii) a part of the top surface of said drain electrode, (iii) at least a part of a surface of said first organic molecular layer, (iv) at least a part of a surface of said second organic molecular layer, and (v) at least a part of a gap between said source electrode and said drain electrode; a gate insulating layer being formed on at least on said organic semiconductor layer; and a gate electrode being formed on said gate insulating layer.

According to the arrangement, after the first and second organic molecular layers are formed, and the organic semiconductor layer is formed thereon, crystal grains in the organic semiconductor layer increase in size due to an effect of a low surface energy of the organic molecular layer. Specifically, crystal grains in the organic semiconductor layer have an increased size in the vicinity of the organic molecular layers. On the other hand, crystal grains which have a direct contact with the source electrode have a small crystal grain size because the crystal grains are affected by a high surface energy of the source electrode. Crystal gains in the organic semiconductor layer have an increased size due to the effect of the first organic molecular layer, at an interface between an area where the first organic molecular layer is formed on the source electrode and an area where no first organic molecular layer is formed on the source electrode. Accordingly, carrier injection from the source electrode is performed directly on such a part where a crystal grain size is large. That is, the carrier injection is performed not via the first organic molecular layer. This results in a high carrier injection efficiency.

The same holds for a drain electrode. The crystal grains in the organic semiconductor layer have a large size in the vicinity of the second organic molecular layer. The carrier injection is performed between the drain electrode and the organic semiconductor layer directly via such a part where a crystal grain size is large. This results in a high carrier injection efficiency. Accordingly, the organic thin-film transistor of the present invention achieves a high efficiency in carrier injection. This makes it possible to obtain a large current.

In order to attain the object, an organic thin-film transistor of the present invention includes: a substrate; a gate electrode being formed on said substrate; a gate insulating layer being formed on said gate electrode; a source electrode being formed on said gate insulating layer; a drain electrode being formed on said gate insulating layer so as to be spaced from said source electrode; a first organic molecular layer which, as a continuous layer, covers (i) a side surface of said source electrode which side surface faces said drain electrode, and (ii) a part of a top surface of said source electrode; a second organic molecular layer which, as a continuous layer, covers (I) a side surface of said drain electrode which side surface faces said source electrode, and (II) a part of a top surface of said drain electrode; an organic semiconductor layer which, as a continuous layer, covers at least a part of a top surface of said first organic molecular layer, at least a part of a top surface of said second organic molecular layer, and at least a part of a gap between said source electrode and said drain electrode; a second source electrode being formed so as to, as a continuous layer, cover a part of the surface of said source electrode, a part of the surface of said first organic molecular layer, and a part of a top surface of said organic semiconductor layer; and a second drain electrode being formed so as to, as a continuous layer, cover a part of the surface of said drain electrode, a part of the surface of said second organic molecular layer, and a part of the top surface of said organic semiconductor layer, said second drain electrode being formed so that on said organic semiconductor layer, said second drain electrode is spaced from said second source electrode.

Further, in order to attain the object, an organic thin-film transistor of the present invention includes: a substrate; a source electrode being formed on said substrate; a drain electrode being formed on said substrate so as to be spaced from said source electrode; a first organic molecular layer which, as a continuous layer, covers (i) a side surface of said source electrode which side surface faces said drain electrode, and (ii) a part of a top surface of said source electrode; a second organic molecular layer which, as a continuous layer, covers (I) a side surface of said drain electrode which side surface faces said source electrode, and (II) a part of a top surface of said drain electrode; an organic semiconductor layer which, as a continuous layer, covers at least a part of a top surface of said first organic molecular layer, at least a part of a top surface of said second organic molecular layer, and at least a part of a gap between said source electrode and said drain electrode; a second source electrode being formed so as to, as a continuous layer, cover a part of the surface of said source electrode, a part of the surface of said first organic molecular layer, and a part of a top surface of said organic semiconductor layer; a second drain electrode being formed so as to, as a continuous layer, cover a part of the surface of said drain electrode, a part of the surface of said second organic molecular layer, and a part of the top surface of said organic semiconductor layer, said second drain electrode being formed so that on said organic semiconductor layer, said second drain electrode is spaced from said second source electrode; a gate insulating layer which, as a continuous layer, covers at least a part of a top surface of said second source electrode, at least a part of a top surface of said second drain electrode, and a part of a gap between said second source electrode and said second drain electrode; and a gate electrode being formed on said gate insulating layer.

According to the arrangement, the first organic molecular layer is provided between the organic semiconductor layer and the source electrode, and the second organic molecular layer is provided between the organic semiconductor layer and the drain electrode. That is, the organic semiconductor layer does not have a direct contact with each of the source electrode and the drain electrode. Accordingly, the first organic molecular layer and the second organic molecular layer serve as resistance components. This results in a low injectability in the carrier injection from the source and drain electrodes. However, according to the arrangement, the second source electrode and the second drain electrode are provided on the organic semiconductor layer. Thus, in the organic thin-film transistor of the present invention, the carrier injection is performed between the organic semiconductor layer and each of the second source electrode and the second drain electrode, not via the organic molecular layer. This makes it possible to increase carrier injection efficiency. As a result, it is possible to obtain a sufficient current.

Further, in order to attain the object, a method of the present invention for manufacturing an organic thin-film transistor, includes the steps of: forming a gate electrode on a substrate; forming a gate insulating layer on the gate electrode; forming a source electrode and a drain electrode on the gate insulating layer so that the source electrode and the drain electrode are spaced from each other; forming a first organic molecular layer which, as a continuous layer, covers (i) a side surface of the source electrode which side surface faces the drain electrode, and (ii) a part of a top surface of the source electrode; forming a second organic molecular layer which, as a continuous layer, covers (I) a side surface of the drain electrode which side surface faces the source electrode, and (II) a part of a top surface of the drain electrode; and forming an organic semiconductor layer which, as a continuous layer, covers at least (i) a part of the top surface of the source electrode, (ii) a part of the top surface of the drain electrode, (iii) at least a part of a surface of the first organic molecular layer, (iv) at least a part of a surface of the second organic molecular layer, and (v) at least a part of a gap between the source electrode and the drain electrode.

Further, in order to attain the object, a method of the present invention for manufacturing an organic thin-film transistor, includes the steps of: forming a gate electrode; forming a source electrode and a drain electrode on a substrate so that the source electrode and the drain electrode are spaced from each other; forming a first organic molecular layer which, as a continuous layer, covers (i) a side surface of the source electrode which side surface faces the drain electrode, and (ii) a part of a top surface of the source electrode; forming a second organic molecular layer which, as a continuous layer, covers (I) a side surface of the drain electrode which side surface faces the source electrode, and (II) a part of a top surface of the drain electrode; forming an organic semiconductor layer which, as a continuous layer, covers at least a part of the top surface of the source electrode, at least a part of the top surface of the drain electrode, at least a part of a surface of the first organic molecular layer, at least a part of a surface of the second organic molecular layer, and at least a part of a gap between the source electrode and the drain electrode; forming a gate insulating layer on at least the organic semiconductor layer; and forming a gate electrode on the gate insulating layer.

The arrangement makes it possible to provide an organic thin-film transistor which achieves a high carrier injection efficiency.

Further, in order to attain the object, a method of the present invention for manufacturing an organic thin-film transistor, includes the steps of: forming a gate electrode on a substrate; forming a gate insulating layer on the gate electrode; forming a source electrode and a drain electrode on the gate insulating layer so that the source electrode and the drain electrode are spaced from each other; forming a first organic molecular layer which, as a continuous layer, covers (i) a side surface of the source electrode which side surface faces the drain electrode, and (ii) a part of a top surface of the source electrode; forming a second organic molecular layer which, as a continuous layer, covers (I) a side surface of the drain electrode which side surface faces the source electrode, and (II) a part of a top surface of the drain electrode; forming an organic semiconductor layer which, as a continuous layer, covers at least a part of a top surface of the first organic molecular layer, at least a part of a top surface of the second organic molecular layer, and at least a part of a gap between the source electrode and the drain electrode; forming a second source electrode which, as a continuous layer, covers a part of the surface of the source electrode, a part of the surface of the first organic molecular layer, and a part of a top surface of the organic semiconductor layer; and forming a second drain electrode which, as a continuous layer, covers a part of the surface of the drain electrode, a part of the surface of the second organic molecular layer, and a part of the top surface of the organic semiconductor layer, the second drain electrode being formed so that on the organic semiconductor layer, the second drain electrode is spaced from the second source electrode.

Further, in order to attain the object, a method of the present invention for manufacturing an organic thin-film transistor, includes the steps of: forming a source electrode and a drain electrode on a substrate so that the source electrode and the drain electrode are spaced from each other; forming a first organic molecular layer which, as a continuous layer, covers (i) a side surface of the source electrode which side surface faces the drain electrode, and (ii) a part of a top surface of the source electrode; forming a second organic molecular layer which, as a continuous layer, covers (I) a side surface of the drain electrode which side surface faces the source electrode, and (II) a part of a top surface of the drain electrode; forming an organic semiconductor layer which, as a continuous layer, covers at least a part of a top surface of the first organic molecular layer, at least a part of a top surface of the second organic molecular layer, and at least a part of a gap between the source electrode and the drain electrode; forming a second source electrode which, as a continuous layer, covers a part of the surface of the source electrode, a part of the surface of the first organic molecular layer, and a part of a top surface of the organic semiconductor layer; forming a second drain electrode which, as a continuous layer, covers a part of the surface of the drain electrode, a part of the surface of the second organic molecular layer, and a part of the top surface of the organic semiconductor layer, the second drain electrode being formed so that on the organic semiconductor layer, the second drain electrode is spaced from the second source electrode; forming a gate insulating layer which, as a continuous layer, covers at least a part of a top surface of the second source electrode, at least a part of a top surface of the second drain electrode, and at least a part of a gap between the second source electrode and the second drain electrode; and forming a gate electrode on the gate insulating layer.

The arrangement makes it possible to provide an organic thin-film transistor which achieves a high carrier injection efficiency.

For a fuller understanding of the nature and advantages of the invention, reference should be made to the ensuing detailed description taken in conjunction with the accompanying drawings.

### Advantageous Effects of Invention

The organic thin-film transistor of the present invention includes the organic molecular layers which cover at least a part of the surface of the source electrode and at least a part of the surface of the drain electrode. Accordingly, the carrier injection between the organic semiconductor layer and each of the source and drain electrodes is performed not via the organic molecular layers. This increases efficiency in hole-electron injection of the organic thin-film transistor. As a result, a large current can be obtained.

### BRIEF DESCRIPTION OF DRAWINGS

FIG. 1 (a) of FIG. 1 is a view illustrating a top surface of an organic thin-film transistor of one embodiment of the present invention. (b) of FIG. 1 is a cross-sectional view illustrating a cross-section taken along the line A-A′ in (a) of FIG. 1.

FIG. 2 (a) of FIG. 2 is a view illustrating a step of forming a photoresist film. (b) of FIG. 2 is a view illustrating a step of depositing an electrode material. (c) of FIG. 2 is a view illustrating a step of forming a source electrode and a drain electrode. (d) of FIG. 2 is a view illustrating a step of forming an organic molecular layer. (e) of FIG. 2 is a view illustrating a step of forming an organic semiconductor layer.

FIG. 3 (a) of FIG. 3 is a view illustrating a step of forming a source electrode and a drain electrode. (b) of FIG. 3 is a view illustrating a step of mounting a metal mask. (c) of FIG. 3 is a view illustrating a step of dropping an organic molecular layer material. (d) of FIG. 3 is a view illustrating a step of forming an organic molecular layer. (e) of FIG. 3 is a view illustrating a step of forming an organic semiconductor layer 7.

FIG. 4 is an enlarged view illustrating the organic semiconductor layer of the organic thin-film transistor of the one embodiment of the present invention.

FIG. 5 (a) of FIG. 5 is a view illustrates a top surface of an organic thin-film transistor of one embodiment of the present invention. (b) of FIG. 5 is a cross-sectional view taken along the line A-A′ in (a) of FIG. 5.

FIG. 6 (a) of FIG. 6 is a view illustrating a step of forming an organic molecular layer. (b) of FIG. 6 is a view illustrating a step of forming an organic semiconductor layer. (c) of FIG. 6 is a view illustrating a step of forming a second source electrode and a second drain electrode.

FIG. 7 (a) of FIG. 7 is a view illustrating a step of forming a source electrode and a drain electrode. (b) of FIG. 7 is a view illustrating a step of mounting a metal mask. (c) of FIG. 7 is a view illustrating a step of dropping an organic molecular layer material. (d) of FIG. 7 is a view illustrating a step of forming an organic molecular layer. (e) of FIG. 7 is a view illustrating a step of forming an organic semiconductor layer. (f) of FIG. 7 is a view illustrating a step of forming a second source electrode and a second drain electrode.

FIG. 8 is an enlarged view illustrating the organic semiconductor layer of the organic thin-film transistor of the one embodiment of the present invention.

FIG. 9 (a) of FIG. 9 is a view illustrates a top surface of an organic thin-film transistor of one embodiment of the present invention. (b) of FIG. 9 is a cross-sectional view taken along the line A-A′ in (a) of FIG. 9.

FIG. 10 (a) of FIG. 10 is a view illustrating a step of forming a source electrode and a drain electrode. (b) of FIG. 10 is a view illustrating a step of mounting a metal mask. (c) of FIG. 10 is a view illustrating a step of dropping an organic molecular layer material. (d) of FIG. 10 is a view illustrating a step of forming an organic molecular layer. (e) of FIG. 10 is a view illustrating a step of forming an organic semiconductor layer. (f) of FIG. 10 is a view illustrating a step of forming a second source electrode and a second drain electrode.

FIG. 11 is an enlarged view illustrating the organic semiconductor layer of the organic thin-film transistor of the one embodiment of the present invention.

FIG. 12 (a) of FIG. 12 is a view illustrates a top surface of an organic thin-film transistor of one embodiment of the present invention. (b) of FIG. 12 is a cross-sectional view taken along the line A-A′ in (a) of FIG. 12.

FIG. 13 (a) of FIG. 13 is a view illustrating a step of forming a source electrode and a drain electrode. (b) of FIG. 13 is a view illustrating a step of mounting a metal mask. (c) of FIG. 13 is a view illustrating a step of dropping an organic molecular layer material. (d) of FIG. 13 is a view illustrating a step of forming an organic molecular layer. (e) of FIG. 13 is a view illustrating a step of forming an organic semiconductor layer. (f) of FIG. 13 is a view illustrating a step of forming a second source electrode and a second drain electrode which are formed by patterning.

FIG. 14 is an enlarged view illustrating the organic semiconductor layer of the organic thin-film transistor of the one embodiment of the present invention.

FIG. 15 is a cross-sectional view illustrating an organic thin-film transistor of a bottom contact structure.

FIG. 16 is a cross-sectional view illustrating that organic thin-film transistor of the bottom contact structure which has an organic molecular layer.

FIG. 17 is an enlarged view illustrating an organic semiconductor layer of that organic thin-film transistor of the bottom contact structure which has an organic molecular layer.

### DESCRIPTION OF EMBODIMENTS

### Embodiment 1

### Arrangement of Organic Thin-Film Transistor 100

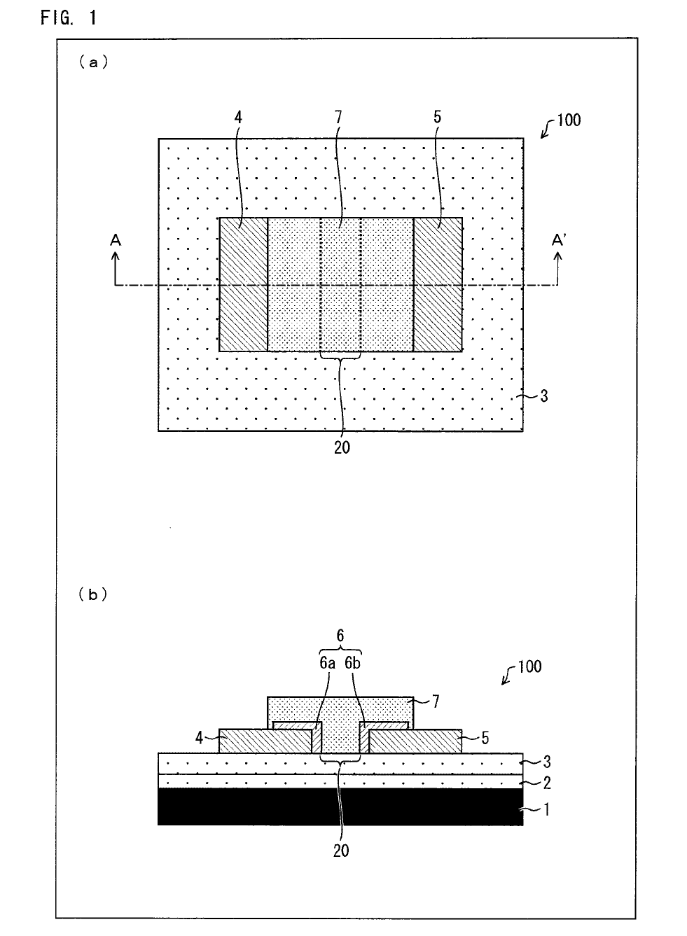

The following describes an arrangement of an organic thin-film transistor 100 of the present embodiment, with reference to FIG. 1. (a) of FIG. 1 is a view illustrating a top surface of the organic thin-film transistor 100. (b) of FIG. 1 is a cross-sectional view illustrating a cross-section taken along the line A-A′ in (a) of FIG. 1.

As illustrated in (b) of FIG. 1, the organic thin-film transistor 100 is a transistor of a bottom contact-type. The organic thin-film transistor 100 includes a substrate 1, a gate electrode 2, a gate insulating layer 3, a source electrode 4, a drain electrode 5, organic molecular layers 6, and an organic semiconductor layer 7. Specifically, the gate electrode 2 is formed on the substrate 1. The gate insulating layer 3 is formed on the gate electrode 2. The source electrode 4 and the drain electrode 5, spaced from each other, are provided on the gate insulating layer 3. A part of a top surface of the source electrode 4 is covered by the first organic molecular layer 6a. Similarly, a part of a top surface of the drain electrode 5 is covered by the second organic molecular layer 6b. Hereinafter, the first organic molecular layer 6a and the second organic molecular layer 6b are collectively referred to as organic molecular layers 6. Although no organic molecular layer 6 is formed in a channel section 20 which is a gap between the source electrode 4 and the drain electrode 5, the organic molecular layers 6 are formed on those surfaces of the electrode 4 and the drain electrode 5 which face the channel section 20. Further, the organic semiconductor layer 7 is formed so as to cover the organic molecular layers 6, the source electrode 4, and the drain electrode 5, and so as to also get into the channel section 20.

### (Overview of Substrate 1)

The following describes the members of the organic thin-film transistor 100 in detail.

First, the following deals with the substrate 1. Examples of materials for the substrate 1 encompass insulating materials such as glass and quartz, and semiconductor materials such as silicon. In a case where the organic thin-film transistor 100 to make is a flexible organic thin-film transistor 100, it is preferable to employ a thin film metal made from stainless steel (SUS), aluminum, or the like, or a plastic material such as polycarbonate, polymethylmethacrylate, polyethersurphone (PES), polyethylenenaphthalate (PEN), polyether ether ketone (PEEK), and polyimide (PI).

### (Overview of Gate Electrode 2)

The following describes the gate electrode 2. Examples of materials for the gate electrode 2 encompass: metal materials such as gold, silver, copper, titanium, and aluminum; an alloy containing at least any one of the metal materials; conductive oxide materials such as indium tin oxide (ITO) and indium zinc oxide (IZO); various semiconductor materials in which, for example, a dopant such as boron or phosphorus is doped, at a high concentration, in any one of silicon, gallium arsenic, etc., and the materials above, so as to increase electrical conductivity of the doped material; various conductive materials such as [poly (3,4-ethylendioxithiophene)poly(styrenesulfonic acid)] (PEDOT: PSS), and polythiophene; and mixtures and compounds of at least any two of the materials above. In order that adhesion between the gate electrode 2 and the substrate 1 is increased, a multilayered gate electrode 2 may be employed which has, e.g., a two-layered structure having a layer made of a material having a good adherability to the substrate 1 and a layer made of the aforementioned material(s) of the gate electrode 2. By employing, as the substrate 1, a low-resistance silicon substrate into which a high concentration of impurity has been injected, it is possible to use the low-resistance silicon substrate itself as the gate electrode 2.

The gate electrode 2 can be formed on the substrate 1 by a physical vapor deposition such as resistance heating, an electronic beam evaporation technique, and sputtering. Further, the gate electrode 2 can also be formed by a printing technique such as ink-jet printing and gravure printing. According to need, patterning can be performed by use of a metal mask or by photolithography.

### (Overview of Gate Insulating Layer 3)

The following describes the gate insulating layer 3. Examples of materials for the gate insulating layer 3 encompass oxide insulating materials such as oxides of silicon, and metals such as aluminum, titanium, etc., and organic insulating materials such as PI.

The gate insulating layer 3 can be formed by a thermal oxidation method, a chemical vapor deposition method, sputtering, spin coating, or the like. In this process, it is preferable to perform surface treatment of the gate insulating layer 3 by use of a self-assembled monomolecular layer such as hexamethyldisilazane and octadecyltrichlorosilane. This makes it possible to improve performance of the organic thin-film transistor 100.

### (Overview of Organic Molecular Layers 6)

The following describes the organic molecular layers 6. Examples of materials for the organic molecular layers 6 encompass an organic thin film made from a material such as polyvinyl phenol, polyvinyl alcohol, PI, and fluororesin, and a self-assembled monomolecular layer. Among them, the self-assembled monomolecular layer has stability because the self-assembled monomolecular layer can be strongly joined to the electrodes due to chemical bonding. Therefore, the self-assembled monomolecular layer is preferably employed as the organic molecular layers 6. In a case where, e.g., the source electrode 4 and the drain electrode 5 are made from a metal such as gold and silver, it is preferable to employ thiol molecules or the like as a material for the self-assembled monomolecular layer. In a case where, e.g., the source electrode 4 and the drain electrode 5 are made from a conductive oxide material such as ITO and IZO, it is preferable to employ silane coupling agent molecules or the like as a material for the self-assembled monomolecular layer.

Although a material for the organic molecular layers 6 is not particularly limited, it is preferable to employ a material having a small surface energy. This is because a material having a small surface energy can cause a material adjacent thereto to be large in grain size. It is preferable to employ a material having many functional groups such as a fluoro group, a chloro group, and a methyl group, as the material having a small surface energy. Examples of the material having many functional groups encompass a fluororesin and a self-assembled monomolecular layer material. Examples of the self-assembled monomolecular layer material encompass thiol molecules such as n-octadecanethiol, perfluorobenzenethiol, and fluorobenzenethiol, silane coupling agents such as octadecyltrichlorosilane and hexamethyldisilazane.

The organic molecular layers 6 can be formed by a coating method utilizing a dispenser, a printing technique such as the ink-jet method, or the like. The organic molecular layers 6 can also be formed by patterning in such a manner that casting of a solution of an organic molecular layer material is cast via a metal mask subjected to fluoro coating or the like, and washing are repeated. In this process, the organic molecular layers 6 are formed on the source electrode 4 and the drain electrode 5 by use of chemical bonding or the like. However, no organic molecular layer 6 is formed in other areas such as in the channel section 20. In this case, accordingly, the organic molecular layer material is preferably one which can be removed by a simple method such as washing. Further, by employing, as the organic molecular layer material, a material which can be deposited, patterning of the organic molecular layers 6 can be performed by a vacuum deposition method or the like which is performed via a metal mask.

### (Overview of Organic Semiconductor Layer 7)

The following describes the organic semiconductor layer 7. Materials which can be employed as those for the organic semiconductor layer 7 are broadly divided into low-molecular materials and high-molecular materials. In general, there are many p-type ones in organic semiconductor materials. Examples of p-type low-molecular materials encompass pentacene and rubrene. Examples of p-type high-molecular materials encompass polythiophene and polyphenylenevinylene.

On the other hand, examples of n-type organic semiconductor materials which can be employed as the organic semiconductor layer 7 are C₆₀ fullerene, perylene, and their derivatives. It is also possible to employ an n-type organic semiconductor material obtained by introducing a fluoro group into a p-type organic semiconductor material such as pentacene and phthalocyanine. Examples of such an n-type organic semiconductor material encompass perfluoropentacene and hexadecafluoro zinc phthalocyanine.

The organic semiconductor layer 7 is formed by different film formation methods depending on whether the organic semiconductor layer 7 is to be made from a low-molecular material or a high-molecular material. In general, low-molecular organic semiconductor molecules have lower boiling points, and are less soluble in a solvent, as compared to high-molecular organic semiconductor molecules. Therefore, in a case where a low-molecular material is employed as the organic semiconductor layer 7, it is preferable to form the organic semiconductor layer 7 by a vacuum deposition method in which resistance heating is performed. In contrast, many of high-molecular organic semiconductor molecules easily dissolve in a solvent. Therefore, in a case where a high-molecular material is employed as the organic semiconductor layer 7, it is preferable to form the organic semiconductor layer 7 by a printing technique such as the ink-jet method.

### (Overview of Source Electrode 4 and Drain Electrode 5)

The following describes the source electrode 4 and the drain electrode 5. Examples of materials for the source electrode 4 and the drain electrode 5 encompass: metal materials such as gold, silver, copper, titanium, and aluminum; alloys containing at least any one of the metal materials; conductive oxide materials such as ITO and IZO; various semiconductor materials in which, for example, a dopant such as boron and phosphorus is injected, at a high concentration, in any one of silicon, gallium arsenic, etc., and the materials above, so as to increase electrical conductivity of the doped material; PEDOT: PSS; various conductive materials such as conductive organic materials such as polythiophene; and mixtures and compounds of at least any two of the materials above.

The source electrode 4 and the drain electrode 5 can be formed by a vacuum deposition method utilizing a metal mask or by physical vapor deposition such as sputtering, in the presence of an inactive gas such as nitrogen and argon.

### (Method for Manufacturing Organic Thin-film Transistor 100)

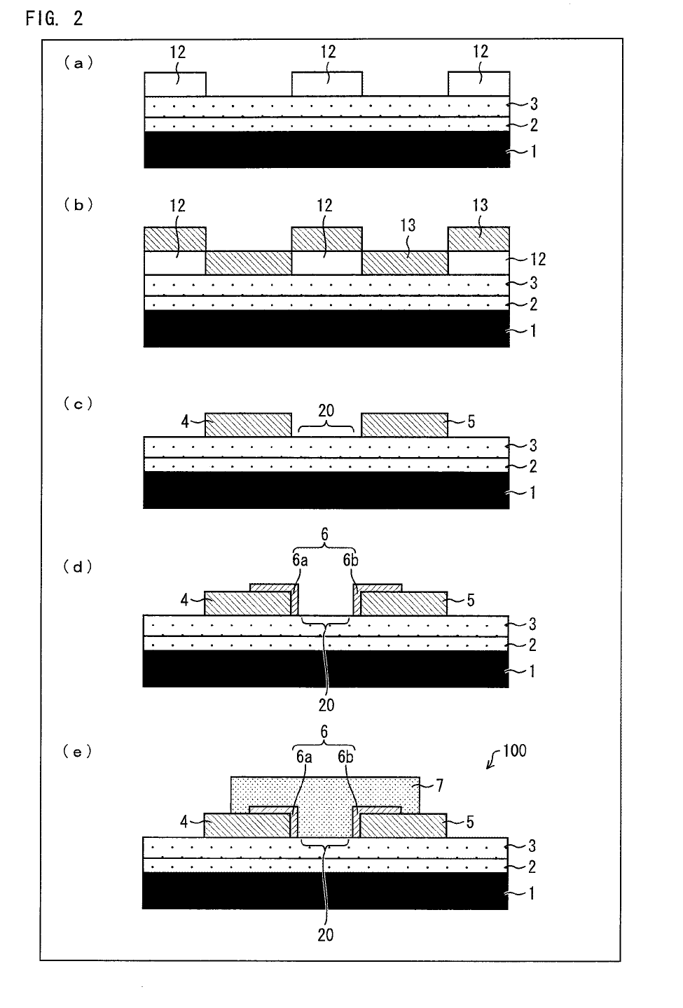

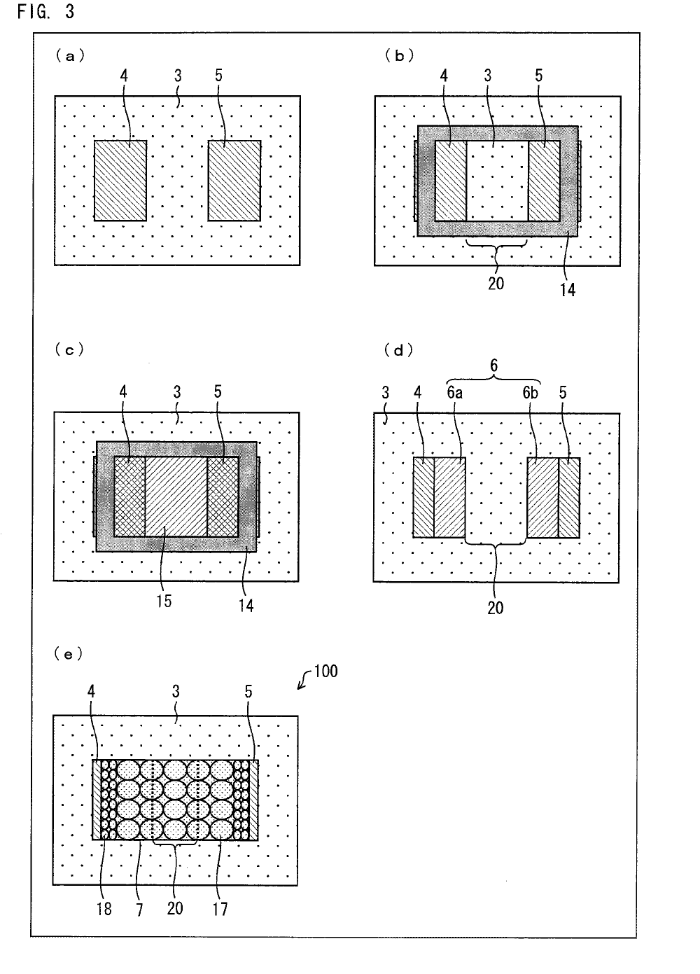

The following describes a method for manufacturing the organic thin-film transistor 100, with reference to FIGS. 2 and 3. (a) of FIG. 2 is a view illustrating a step of forming a photoresist film 12. (b) of FIG. 2 is a view illustrating a step of depositing an electrode material 13. (c) of FIG. 2 is a view illustrating a step of forming the source electrode 4 and the drain electrode 5. (d) of FIG. 2 is a view illustrating a step of forming the organic molecular layers 6. (e) of FIG. 2 is a view illustrating a step of forming the organic semiconductor layer 7. (a) of FIG. 3 is a view illustrating a step of forming the source electrode 4 and the drain electrode 5. (b) of FIG. 3 is a view illustrating a step of mounting a metal mask 14. (c) of FIG. 3 is a view illustrating a step of dropping an organic molecular layer material 15. (d) of FIG. 3 is a view illustrating a step of forming the organic molecular layers 6. (e) of FIG. 3 is a view illustrating a step of forming the organic semiconductor layer 7.

First, the gate electrode 2 is formed on the substrate 1, and the gate insulating layer 3 is formed thereon. Then, as illustrated in (a) of FIG. 2, the photoresist film 12 having openings is formed on the gate insulating layer 3. Then, as illustrated in (b) of FIG. 2, the electrode material 13 is deposited on the substrate 1 on which the photoresist film 12 has been thus formed. Then, the photoresist film 12 is removed so that as illustrated in (c) of FIG. 2, the electrode material 13 deposited in the openings of the photoresist film 12 is left on the substrate 1. The source electrode 4 and the drain electrode 5 are thus formed on the substrate 1 ((a) of FIG. 3).

After the source electrode 4 and the drain electrode 5 are thus formed on the substrate 1, the metal mask 14 having an opening is placed on the source electrode 4 and the drain electrode 5 ((b) of FIG. 3). Specifically, the metal mask 14 is placed so that an area of the opening of the metal mask 14 encompasses (i) a part of a surface of each of the source electrode 4 and the drain electrode 5, and (ii) a surface of the channel section 20 which is a gap between the source electrode 4 and the drain electrode 5.

Then, the organic molecular layer material 15 is dropped from above the metal mask 14 so that the organic molecular material 15 is dropped in the area of the opening of the metal mask 14, namely, dropped on a part of a surface of each of the source electrode 4 and the drain electrode 5 and on the channel section 20 ((c) of FIG. 3). The metal mask 14 is subjected to, e.g., fluoro coating in advance so that the organic molecular layer material 15 does not permeate an area other than the area of the opening.

Then, substrate 1 is washed and the metal mask 14 is removed. As a result of the washing, the organic molecular material 15 in the channel section 20 is removed whereby, the organic molecular layers 6 is formed on a part of a surface of each of the source electrode 4 and the drain electrode 5 ((d) of FIG. 3). Specifically, as illustrated in (d) of FIG. 2, a first organic molecular layer 6a is formed on a part of a top surface of the source electrode 4, and similarly, a second organic molecular layer 6b is formed on a part of a top surface of the drain electrode 5. The first organic molecular layer 6a is formed so as to, as a continuous layer, cover (i) the part of the top surface of the source electrode 4 and (ii) that surface of the source electrode 4 which faces the channel section 20 (i.e., a side surface of the source electrode 4). Similarly, the second organic molecular layer 6b is formed so as to, as a continuous layer, cover (i) the part of the top surface of the drain electrode 5 and (ii) that surface of the drain electrode 5 which faces the channel section 20 (i.e., a side surface of the drain electrode 5).

Finally, the organic semiconductor layer 7 is formed on the organic molecular layers 6 ((e) of FIG. 3). In this process, as illustrated in (e) of FIG. 2, the organic semiconductor layer 7 is formed so as to cover the channel section 20, the organic molecular layers 6, and that part of a surface of each of the source electrode 4 and the drain electrode 5 in which no organic molecular layer 6 is formed. The organic thin-film transistor 100 is thus formed in this manner.

In a case where a material other than the self-assembled monomolecular layer is employed as a material for the organic molecular layers 6, it is possible to omit the steps illustrated in (b) and (c) of FIG. 3. That is, it is possible to form the organic molecular layers 6 by directly applying the organic molecular layer material 15 by use of a dispenser onto the source electrode 4 and the drain electrode 5 which are formed on the substrate 1.

### (Carrier Injectability of Organic Thin-film Transistor 100)

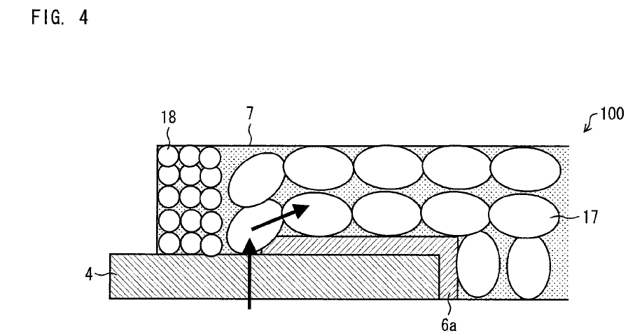

The above has dealt with the method for manufacturing the organic thin-film transistor 100. Crystal grains in the organic semiconductor layer 7 increase in size in the formation of the organic semiconductor layer 7 on the organic molecular layers 6. The following concretely describes this in detail, with reference to FIG. 4. FIG. 4 is an enlarged view illustrating the organic semiconductor layer 7 of the organic thin-film transistor 100.

After the organic molecular layers 6 are formed and the organic semiconductor material is then placed thereon, the crystal grains of the organic semiconductor material increase in size due to an effect of a low surface energy of the organic molecular layers 6. In the organic thin-film transistor 100, as illustrated in FIG. 4, crystals 17 in the organic semiconductor layer 7 are larger in size in the vicinity of the organic molecular layer 6. On the other hand, crystals 18 which have a direct contact with the source electrode 4 are smaller in crystal grain size because the crystals 18 are affected by a high surface energy of the source electrode 4. Crystal gains in the organic semiconductor layer 7 are grown larger in size due to the effect of the first organic molecular layer 6a, at an interface between an area where the first organic molecular layer 6a is formed on the source electrode 4 and an area where no first organic molecular layer 6a is formed on the source electrode 4. Accordingly, carrier injection from the source electrode 4 is performed directly on such a part where the organic semiconductor layer 7 is large in crystal grain size. That is, the carrier injection is performed not via the first organic molecular layer 6a. This results in a high carrier injection efficiency.

The same holds for a drain electrode 5 side. The crystal grains in the organic semiconductor layer 7 are large in size in the vicinity of the second organic molecular layer 6b. The carrier injection is performed between the drain electrode 5 and the organic semiconductor layer 7 directly via such a part where the organic semiconductor layer 7 is large in crystal grain size. This results in a high carrier injection efficiency. Accordingly, the organic thin-film transistor 100 of the present embodiment achieves a high efficiency of hole-electron injection. This makes it possible to obtain a large current. By thus providing the organic molecular layers 6 on a part of a surface of each of the source electrode 4 and the drain electrode 5, it is possible to improve the performance of the organic thin-film transistor 100.

### Embodiment 2

### Arrangement of Organic Thin-Film Transistor 200

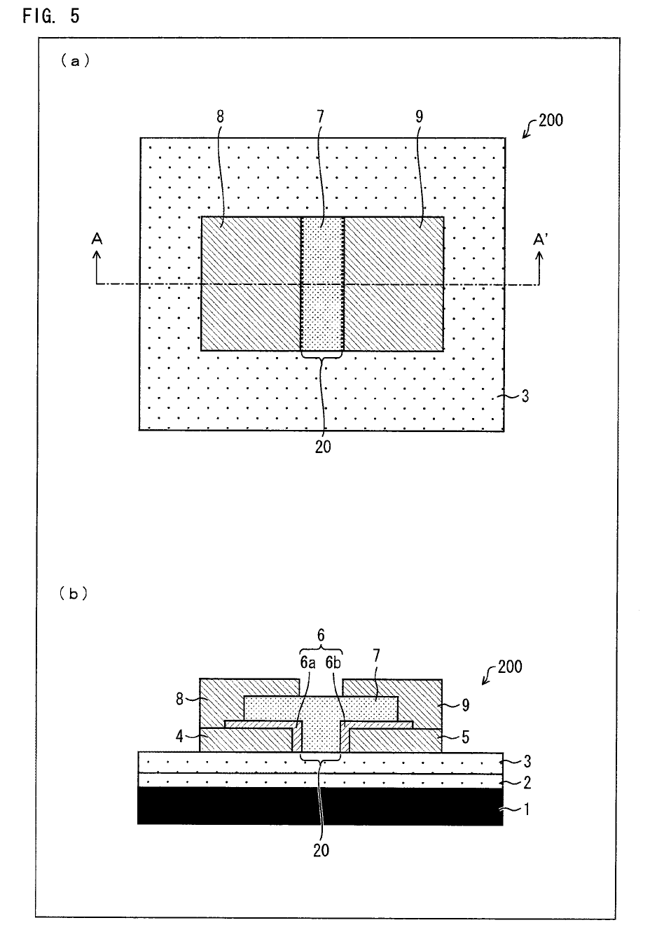

An organic thin-film transistor 200 of the present embodiment is characterized by including a second source electrode 8 and a second drain electrode 9. The following concretely describes this, with reference to FIG. 5. (a) of FIG. 5 illustrates a top surface of the organic thin-film transistor 200. (b) of FIG. 5 is a cross-sectional view taken along the line A-A′ in (a) of FIG. 5.

As illustrated in (b) of FIG. 5, the organic thin-film transistor 200 is a bottom contact-type transistor. The organic thin-film transistor 200 includes a substrate 1, a gate electrode 2, a gate insulating layer 3, a source electrode 4, a drain electrode 5, organic molecular layers 6, an organic semiconductor layer 7, the second source electrode 8, and the second drain electrode 9. Specifically, the gate electrode 2 is formed on the substrate 1. The gate insulating layer 3 is formed on the gate electrode 2. The source electrode 4 and the drain electrode 5 are provided on the gate insulating layer 3 so as to have a space therebetween. A part of a top surface of the source electrode 4 is covered by the first organic molecular layer 6a. Similarly, a part of a top surface of the drain electrode 5 is covered by the second organic molecular layer 6b. Although no organic molecular layer 6 is formed in a channel section 20 which is a gap between the source electrode 4 and the drain electrode 5, the organic molecular layer 6 is formed on that surface of each of the electrode 4 and the drain electrode 5 which faces the channel section 20. Further, the organic semiconductor layer 7 is formed so as to cover the organic molecular layers 6 and also get into the channel section 20. The organic semiconductor layer 7 has no contact with the source electrode 4 nor with the drain electrode 5.

Further, the second source electrode 8 and the second drain electrode 9 are formed on the organic semiconductor layer 7. Specifically, the second source electrode 8 is formed so as to have a contact with the source electrode 4 and with the first organic molecular layer 6a and so that the organic semiconductor layer 7 is sandwiched between the second source electrode 8 and the first organic molecular layer 6a. Similarly, the second drain electrode 9 is formed so as to have a contact with the drain electrode 5 and with the second organic molecular layer 6b and so that the organic semiconductor layer 7 is sandwiched between the second drain electrode 9 and the first organic molecular layer 6b. The second source electrode 8 and the source electrode 4 are electrically connected due to a direct contact therebetween. Similarly, the second source electrode 9 and the drain electrode 5 are electrically connected due to a direct contact therebetween. Although each of the second source electrode 8 and the second drain electrode 9 is formed so as to have a contact with a top surface of the organic semiconductor layer 7, the second source electrode 8 and the second drain electrode 9 are formed so as not to have a contact with each other. It is possible to employ, as a material for the second source electrode 8 and the second drain electrode 9, the material for the source electrode 4 and the drain electrode 5.

### (Method for Manufacturing Organic Thin-Film Transistor 200)

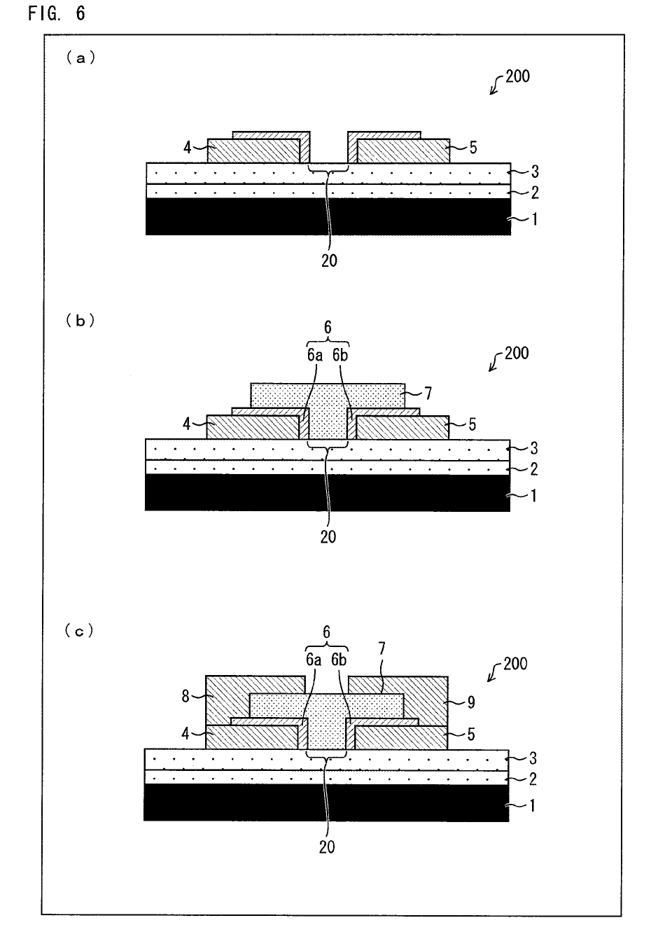

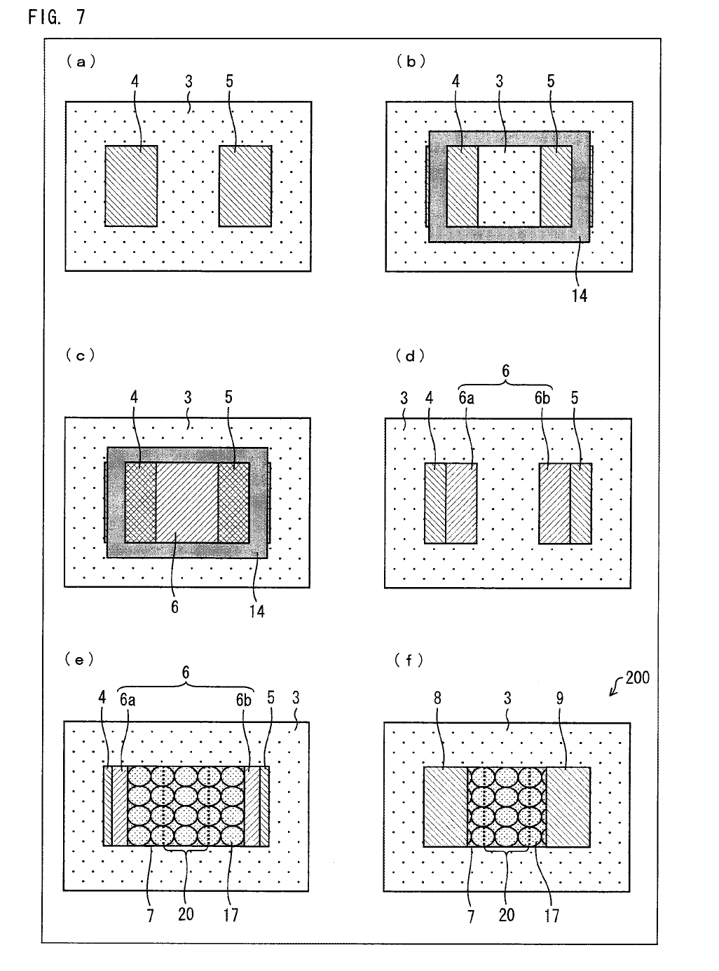

The following describes a method for manufacturing the organic thin-film transistor 200, with reference to FIGS. 6 and 7. (a) of FIG. 6 is a view illustrating a step of forming the organic molecular layers 6. (b) of FIG. 6 is a view illustrating a step of forming the organic semiconductor layer 7. (c) of FIG. 6 is a view illustrating a step of forming the second source electrode 8 and the second drain electrode 9. Steps illustrated in (a) through (d) of FIG. 7 are the same as those of Embodiment 1 (the steps illustrated in (a) through (d) of FIG. 3), the following omits to describe the steps. (e) of FIG. 7 is a view illustrating a step of forming the organic semiconductor layer 7. (f) of FIG. 7 is a view illustrating a step of forming the second source electrode 8 and the second drain electrode 9.

Since the steps to be performed until the organic molecular layers 6 are formed on the substrate 1 are common between the present embodiment and Embodiment 1, the following omits to describe the steps. The following description starts with a step of forming the organic semiconductor layer 7.

The organic semiconductor layer 7 is formed on the substrate 1 on which the organic molecular layers 6 have been formed ((e) of FIG. 7). In this process, as illustrated in (b) of FIG. 6, the organic semiconductor layer 7 is formed so as to, as a continuous layer, cover the channel section 20 and the organic molecular layers 6. Note that the organic semiconductor layer 7 is formed so as not to have a contact with the source electrode 4 and with the drain electrode 5.

Finally, the second source electrode 8 and the second drain electrode 9 are formed on the organic semiconductor layer 7 ((f) of FIG. 7). Specifically, the second source electrode 8 is formed so as to, as a continuous layer, cover (i) a part of a surface of the source electrode 4, (ii) a part of a surface of the first organic molecular layer 6a, and (iii) a part of a top surface of the organic semiconductor layer 7. Similarly, the second drain electrode 9 is formed so as to, as a continuous layer, cover (i) a part of a surface of the drain electrode 5, (ii) a part of a surface of the second organic molecular layer 6b, and (iii) a part of the top surface of the organic semiconductor layer 7. The organic thin-film transistor 200 is thus formed.

### (Carrier Injectability of Organic Thin-Film Transistor 200)

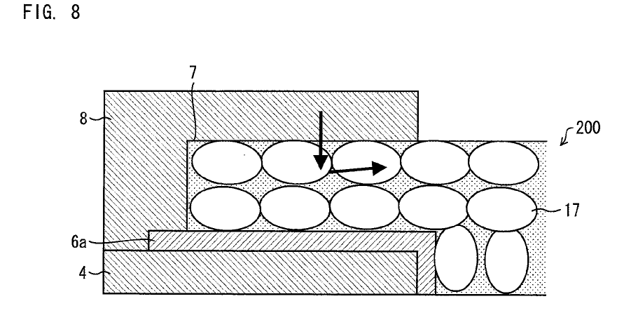

As described above, crystal grains in the organic semiconductor layer 7 increase in size in the formation of the organic semiconductor layer 7 on the organic molecular layers 6. The following concretely describes this in detail, with reference to FIG. 8. FIG. 8 is an enlarged view of the organic semiconductor layer 7 of the organic thin-film transistor 200.

After the organic molecular layer 6 is formed and the organic semiconductor material is then placed thereon, the crystal grains of the organic semiconductor material increase in size due to an effect of a low surface energy of the organic molecular layer 6. In the organic thin-film transistor 200, as illustrated in FIG. 8, crystals 17 in the organic semiconductor layer 7 have grown large in size in the vicinity of the organic molecular layer 6. The organic semiconductor layer 7 of the organic thin-film transistor 200 hardly has a direct contact with the source electrode 4 and with the drain electrode 5. Therefore, the organic semiconductor layer 7 hardly has small crystal grains. Under the second source electrode 8, crystal gains in the organic semiconductor layer 7 have grown large in size due to an effect of the first organic molecular layer 6a. Accordingly, carrier injection from the source electrode 4, namely, from the second source electrode 8, is performed directly on such a part where the organic semiconductor layer 7 is large in crystal grain size. Thus, the carrier injection is performed not via the first organic molecular layer 6a. This results in a high carrier injection efficiency.

The same holds for a drain electrode 5 side. The crystal grains in the organic semiconductor layer 7 have a large size in the vicinity of the second organic molecular layer 6b, and also under the second drain electrode 9. The carrier injection is performed between the drain electrode 5, namely, the second drain electrode 9, and the organic semiconductor layer 7 directly via such a part where the organic semiconductor layer 7 is large in crystal grain size. This results in a high carrier injection efficiency. Accordingly, the organic thin-film transistor 200 of the present embodiment achieves a high efficiency of hole-electron injection. This makes it possible to obtain a large current. By thus providing the organic molecular layer 6 on each of the source electrode 4 and the drain electrode 5, and further providing the second source electrode 8 and the second drain electrode 9, it is possible to improve the performance of the organic thin-film transistor 200.

### Embodiment 3

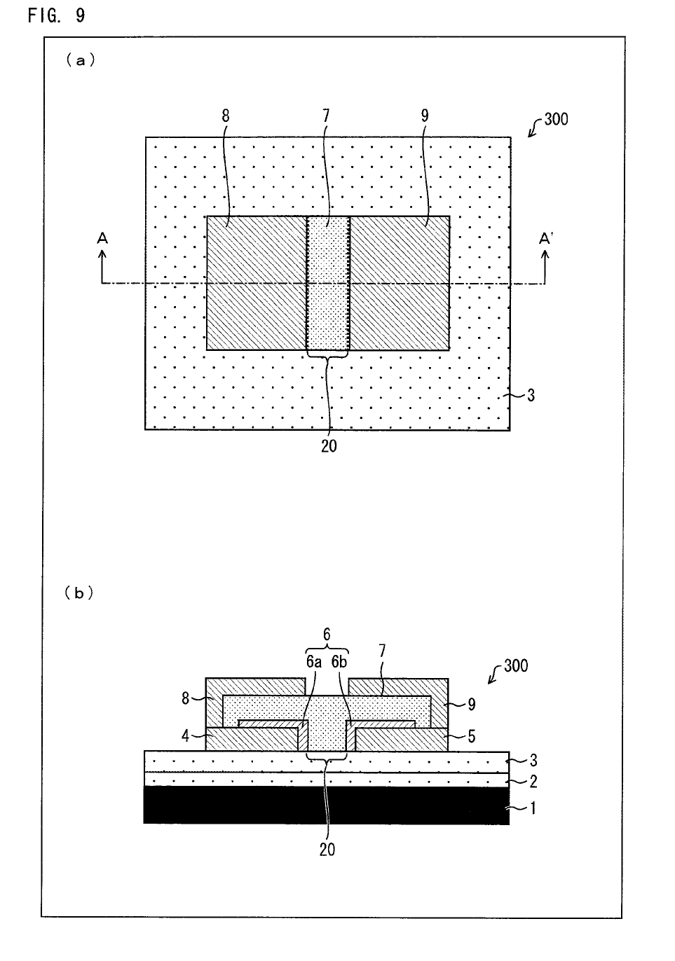

As is the case with Embodiment 2, an organic thin-film transistor 300 of the present embodiment includes a second source electrode 8 and a second drain electrode 9. However, the organic semiconductor layer 7 is provided so as to have a contact with a part of a top surface of each of the source electrode 4 and the drain electrode 5. The following concretely describes this, with reference to FIG. 9. (a) of FIG. 9 illustrates a top surface of the organic thin-film transistor 300. (b) of FIG. 9 is a cross-sectional view taken along the line A-A′ in (a) of FIG. 9.

As illustrated in (b) of FIG. 9, the organic thin-film transistor 300 is a bottom contact-type transistor. The organic thin-film transistor 300 includes a substrate 1, a gate electrode 2, a gate insulating layer 3, a source electrode 4, a drain electrode 5, an organic molecular layer 6, an organic semiconductor layer 7, the second source electrode 8, and the second drain electrode 9. Specifically, the gate electrode 2 is formed on the substrate 1. The gate insulating layer 3 is formed on the gate electrode 2. The source electrode 4 and the drain electrode 5 are provided on the gate insulating layer 3 so as to have a space therebetween. A part of a top surface of the source electrode 4 is covered by the first organic molecular layer 6a. Similarly, a part of a top surface of the drain electrode 5 is covered by the second organic molecular layer 6b. Although no organic molecular layer 6 is formed in a channel section 20 which is a gap between the source electrode 4 and the drain electrode 5, the organic molecular layer 6 is formed on that surface of each of the electrode 4 and the drain electrode 5 which faces the channel section 20. Further, the organic semiconductor layer 7 is formed so as to cover the organic molecular layer 6, the source electrode 4, and the drain electrode 5, and also get into the channel section 20.

Further, the second source electrode 8 and the second drain electrode 9 are formed on the organic semiconductor layer 7. Specifically, the second source electrode 8 is formed so as to have a contact with the source electrode 4 and so that the organic semiconductor layer 7 is sandwiched between the second source electrode 8 and the source electrode 4. Similarly, the second drain electrode 9 is formed so as to have a contact with the drain electrode 5 and so that the organic semiconductor layer 7 is sandwiched between the second drain electrode 9 and the drain electrode 5. The second source electrode 8 and the source electrode 4 are electrically connected due to a direct contact therebetween. Similarly, the second drain electrode 9 and the drain electrode 5 are electrically connected due to a direct contact therebetween. Although each of the second source electrode 8 and the second drain electrode 9 is formed so as to have a contact with a top surface of the organic semiconductor layer 7, the second source electrode 8 and the second drain electrode 9 are formed so as not to have a contact with each other.

### (Method for Manufacturing Organic Thin-Film Transistor 300)

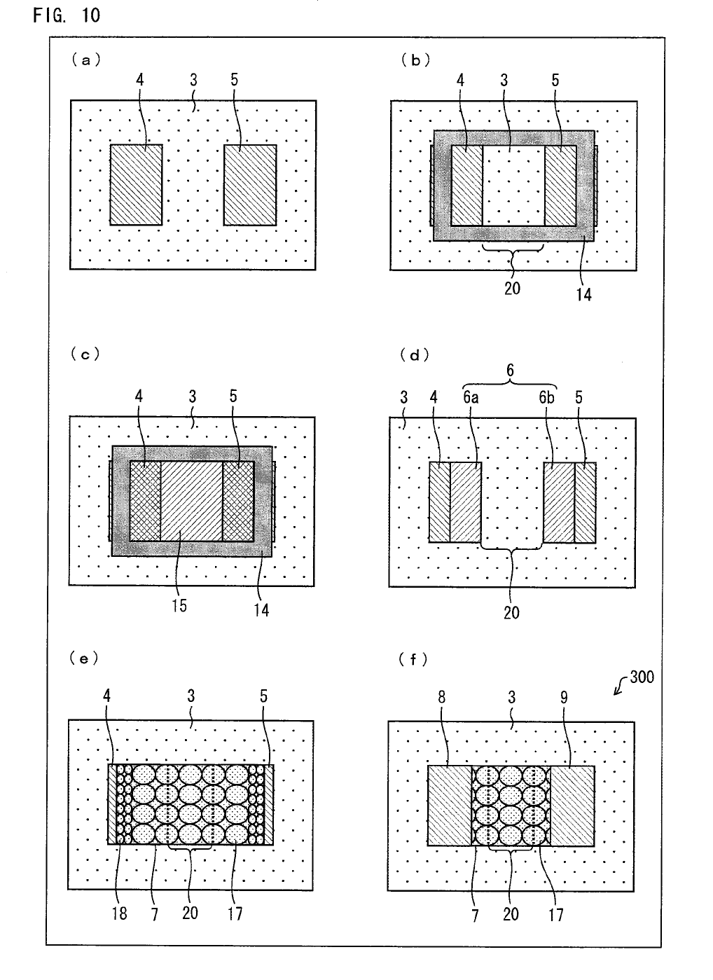

The following describes a method for manufacturing the organic thin-film transistor 300, with reference to FIG. 10. Steps illustrated in (a) through (e) of FIG. 10 are the same as those of Embodiment 1 (the steps illustrated in (a) through (e) of FIG. 3), the following omits to describe the steps. (f) of FIG. 10 is a view illustrating a step of forming the second source electrode 8 and the second drain electrode 9.

Since the steps to be performed until the organic semiconductor layer 7 is formed on the substrate 1 are common between the present embodiment and Embodiment 1, the following omits to describe the steps. The following description starts with a step of forming the second source electrode 8 and the second drain electrode 9.

The second source electrode 8 and the second drain electrode 9 are formed on the substrate 1 on which the organic semiconductor layer 7 has been formed ((f) of FIG. 10). Specifically, the second source electrode 8 is formed so as to, as a continuous layer, cover (i) a part of a surface of the source electrode 4, and (ii) a part of a top surface of organic semiconductor layer 7. Similarly, the second drain electrode 9 is formed so as to, as a continuous layer, cover (i) a part of a surface of the drain electrode 5, and (ii) a part of the top surface of the organic semiconductor layer 7. More specifically, the second source electrode 8 and the second drain electrode 9 are formed so as to entirely cover the top surface of the organic semiconductor layer 7. The organic thin-film transistor 300 is thus formed.

### (Carrier Injectability of Organic Thin-Film Transistor 300)

As described above, crystal grains in the organic semiconductor layer 7 increase in size in the formation of the organic semiconductor layer 7 on the organic molecular layers 6. The following concretely describes this in detail, with reference to FIG. 11. FIG. 11 is an enlarged view of the organic semiconductor layer 7 of the organic thin-film transistor 300.

After the organic molecular layers 6 are formed and the organic semiconductor material is then placed thereon, the crystal grains of the organic semiconductor material increase in size due to an effect of a low surface energy of the organic molecular layers 6. In the organic thin-film transistor 300, as illustrated in FIG. 11, crystals 17 in the organic semiconductor layer 7 have an increased size in the vicinity of the organic molecular layer 6. On the other hand, crystals 18 which have a direct contact with the source electrode 4 have a small crystal grain size due to an effect of a high surface energy of the source electrode 4. Crystal gains in the organic semiconductor layer 7 have an increased size due to the effect of the first organic molecular layer 6a, at an interface between an area where the first organic molecular layer 6a is formed on the source electrode 4 and an area where no first organic molecular layer 6a is formed on the source electrode 4. Accordingly, carrier injection from the source electrode 4 is performed directly on such a part where a crystal grain size is large.

Under the second source electrode 8, crystal gains in the organic semiconductor layer 7 have an increased size due to an effect of the first organic molecular layer 6a. Accordingly, carrier injection from the second source electrode 8 is performed directly also on such a part where a crystal grain size is large. That is, the carrier injection is performed not via the first organic molecular layer 6a but via the source electrode 4 and the second source electrode 8. This significantly increases a carrier injection efficiency.

The same holds for a drain electrode 5 side. The crystal grains in the organic semiconductor layer 7 have a large size in the vicinity of the second organic molecular layer 6b, and also under the second drain electrode 9. The carrier injection between the organic semiconductor layer 7 and each of the drain electrode 5 and the second drain electrode 9 is performed directly via such a part where a crystal grain size is large. This results in a high carrier injection efficiency. Accordingly, the organic thin-film transistor 300 of the present embodiment achieves a high efficiency of hole-electron injection. This makes it possible to obtain a large current. By thus providing the organic molecular layers 6 on a part of a surface of each of the source electrode 4 and the drain electrode 5, and further providing the second source electrode 8 and the second drain electrode 9, it is possible to improve the performance of the organic thin-film transistor 300.

### Embodiment 4

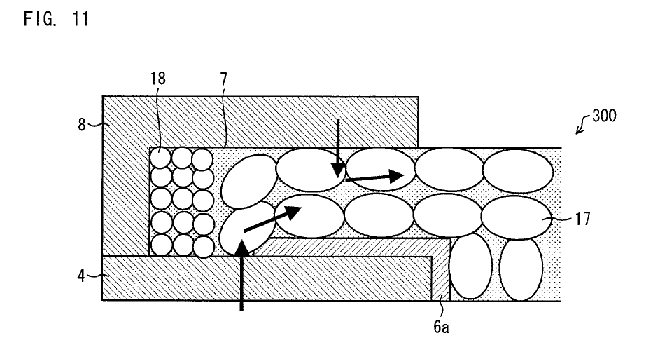

As is the case with Embodiment 3, an organic thin-film transistor 400 of the present embodiment includes an organic molecular layer 6 on a part of a surface of each of a source electrode 4 and a drain electrode 5, and a second source electrode 8 and a second drain electrode 9. However, the organic thin-film transistor 400 has such a feature that a contact area is smaller between an organic semiconductor layer 7 and each of the second source electrode 8 and the second drain electrode 9, as compared to Embodiment 3. The following concretely describes this, with reference to FIG. 12. (a) of FIG. 12 illustrates a top surface of the organic thin-film transistor 400. (b) of FIG. 12 is a cross-sectional view taken along the line A-A′ in (a) of FIG. 12.

As illustrated in (b) of FIG. 12, the organic thin-film transistor 400 is a bottom contact-type transistor. The organic thin-film transistor 400 includes a substrate 1, a gate electrode 2, a gate insulating layer 3, a source electrode 4, a drain electrode 5, organic molecular layers 6, an organic semiconductor layer 7, the second source electrode 8, and the second drain electrode 9. Specifically, the gate electrode 2 is formed on the substrate 1. The gate insulating layer 3 is formed on the gate electrode 2. The source electrode 4 and the drain electrode 5 are provided on the gate insulating layer 3 so as to have a space therebetween. A part of a top surface of the source electrode 4 is covered by the first organic molecular layer 6a. Similarly, a part of a top surface of the drain electrode 5 is covered by the second organic molecular layer 6b. Although no organic molecular layer 6 is formed in a channel section 20 which is a gap between the source electrode 4 and the drain electrode 5, the organic molecular layer 6 is formed on that surface of each of the source electrode 4 and the drain electrode 5 which faces the channel section 20. Further, the organic semiconductor layer 7 is formed so as to cover the organic molecular layers 6, the source electrode 4, and the drain electrode 5, and also get into the channel section 20.

Further, the second source electrode 8 and the second drain electrode 9 are formed on the organic semiconductor layer 7. Specifically, the second source electrode 8 is formed so as to have a contact with the source electrode 4 and so that a part of the organic semiconductor layer 7 is sandwiched between the second source electrode 8 and the source electrode 4. Similarly, the second drain electrode 9 is formed so as to have a contact with the drain electrode 5 and so that a part of the organic semiconductor layer 7 is sandwiched between the second drain electrode 9 and the drain electrode 5. The second source electrode 8 and the source electrode 4 are electrically connected due to a direct contact therebetween. Similarly, the second source electrode 9 and the drain electrode 5 are electrically connected due to a direct contact therebetween. Each of the second source electrode 8 and the second drain electrode 9 is formed so as to have a contact with a top surface of the organic semiconductor layer 7. On the other hand, the second source electrode 8 and the second drain electrode 9 are formed so as not to have a contact with each other.

### (Method for Manufacturing Organic Thin-Film Transistor 400)

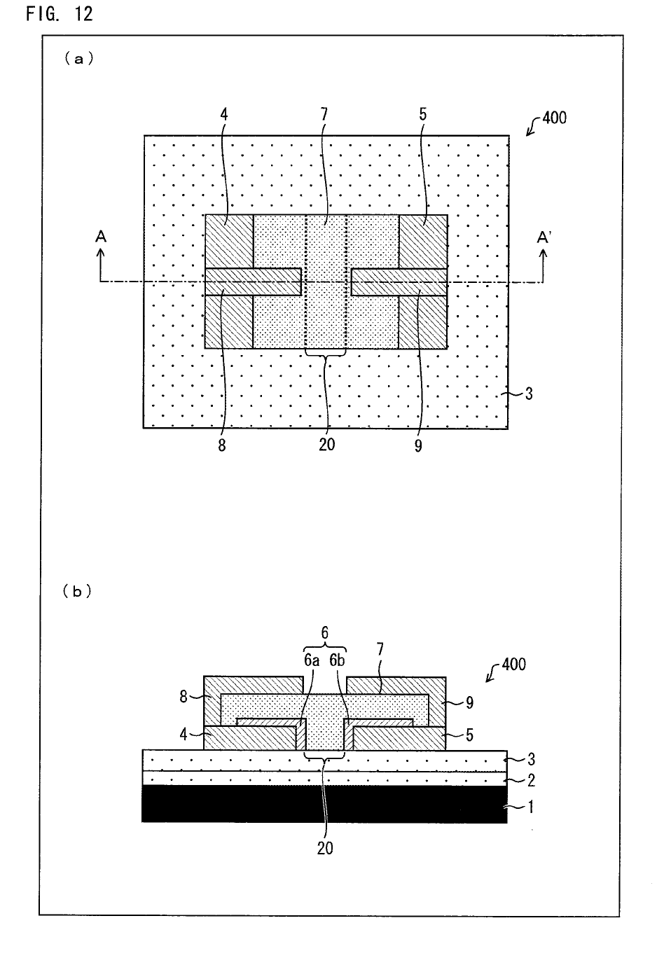

The following describes a method for manufacturing the organic thin-film transistor 400, with reference to FIG. 13. Steps illustrated in (a) through (e) of FIG. 13 are the same as those of Embodiment 3 (the steps illustrated in (a) through (e) of FIG. 10), the following omits to describe the steps. (f) of FIG. 13 is a view illustrating a step of forming the second source electrode 8 and the second drain electrode 9 patterned by patterning.

Since the steps to be performed until the organic semiconductor layer 7 is formed on the substrate 1 are common between the present embodiment and Embodiment 3, the following omits to describe the steps. The following description starts with a step of forming the second source electrode 8 and the second drain electrode 9 by patterning.

The second source electrode 8 and the second drain electrode 9 patterned by patterning are formed on the substrate 1 ((f) of FIG. 13). Specifically, pattern formation of the second source electrode 8 is performed by use of a metal mask so that the second source electrode 8 does not entirely cover the top surface of the organic semiconductor layer 7 but has a contact with a part of the top surface of the organic semiconductor layer 7. Similarly, pattern formation of the second drain electrode 9 is performed by use of a metal mask so that the second drain electrode 9 does not entirely cover the top surface of the organic semiconductor layer 7 but has a contact with a part of the top surface of the organic semiconductor layer 7. The organic thin-film transistor 400 is thus formed.

### (Carrier Injectability of Organic Thin-Film Transistor 300)

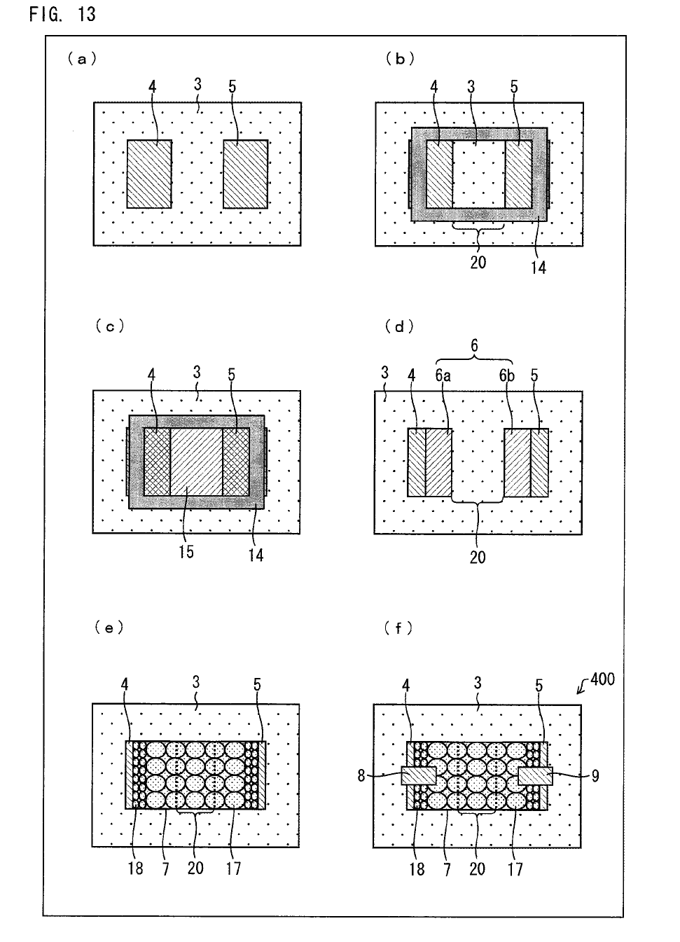

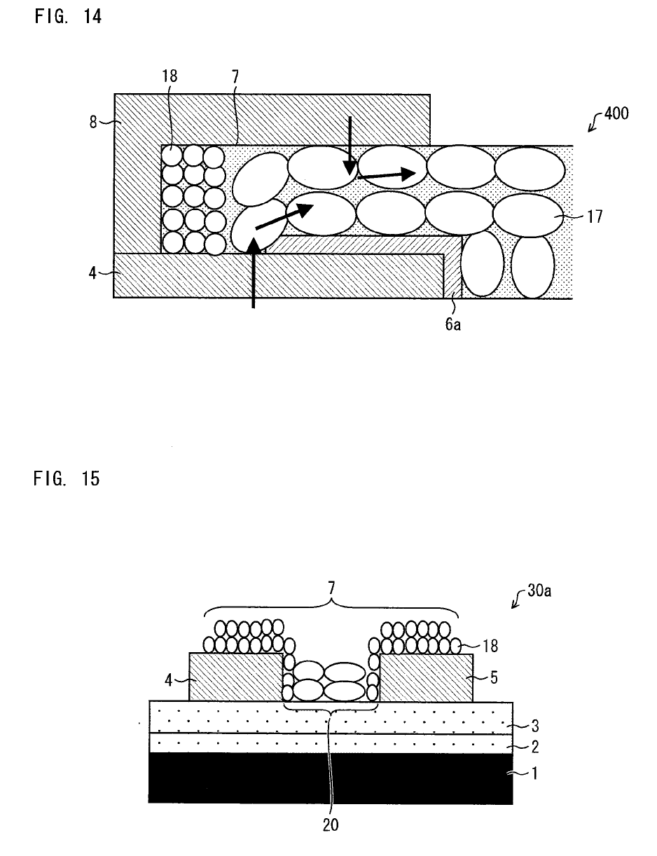

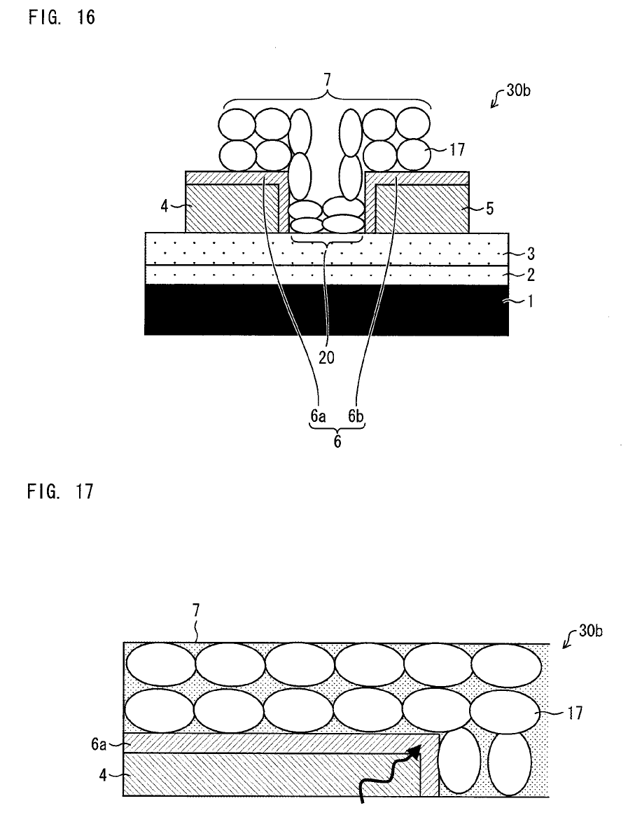

As described above, crystal grains in the organic semiconductor layer 7 increase in size in the formation of the organic semiconductor layer 7 on the organic molecular layers 6. The following concretely describes this in detail, with reference to FIG. 14. FIG. 14 is an enlarged view of the organic semiconductor layer 7 of the organic thin-film transistor 400.

After the organic molecular layers 6 are formed and the organic semiconductor material is then placed thereon, the crystal grains of the organic semiconductor material increase in size due to an effect of a low surface energy of the organic molecular layers 6. In the organic thin-film transistor 400, as illustrated in FIG. 14, crystals 17 in the organic semiconductor layer 7 have an increased size in the vicinity of the organic molecular layer 6. On the other hand, crystals 18 which have a direct contact with the source electrode 4 are small in crystal grain size due to an effect of a high surface energy of the source electrode 4. Crystal gains in the organic semiconductor layer 7 have grown large in size due to the effect of the first organic molecular layer 6a, at an interface between an area where the first organic molecular layer 6a is formed on the source electrode 4 and an area where no first organic molecular layer 6a is formed on the source electrode 4. Accordingly, carrier injection from the source electrode 4 is performed directly on such a part where the organic semiconductor layer 7 is large in crystal grain size.

Under the second source electrode 8, crystal gains in the organic semiconductor layer 7 have grown large in size due to an effect of the first organic molecular layer 6a. Accordingly, carrier injection from the second source electrode 8 is performed directly also on such a part where the organic semiconductor layer 7 have is large in crystal grain size. That is, the carrier injection is performed from both of the source electrode 4 and the second source electrode 8 to the organic semiconductor layer 7 not via the organic molecular layer 6. This significantly increases a carrier injection efficiency.

The same holds for a drain electrode 5 side. The crystal grains in the organic semiconductor layer 7 are large in size in the vicinity of the second organic molecular layer 6b, and also under the second drain electrode 9. The carrier injection between the organic semiconductor layer 7 and each of the drain electrode 5 and the second drain electrode 9 is performed directly via such a part where the organic semiconductor layer 7 is large in crystal grain size. This results in a high carrier injection efficiency. Accordingly, the organic thin-film transistor 400 of the present embodiment achieves a high efficiency of hole-electron injection. This makes it possible to obtain a large current. By thus providing the organic molecular layer 6 on a part of a surface of each of the source electrode 4 and the drain electrode 5, and further providing the second source electrode 8 and the second drain electrode 9 on at least a part of the surface of the organic semiconductor layer 7, it is possible to improve the performance of the organic thin-film transistor 400.

As described above, an arrangement of the second source electrode 8 and the second drain electrode 9 is not limited to such an arrangement that as described in Embodiment 3, the second source electrode 8 and the second drain electrode 9 are formed so as to cover substantially the entire top surface of the organic semiconductor layer 7. A shape of the second source electrode 8 is not particularly limited, provided that as described in Embodiment 4, the second source electrode 8, as a continuous layer, covers a part of the surface of the source electrode 4, a part of the surface of the first organic molecular layer 6a, and a part of the top surface of the organic semiconductor layer 7. The same holds for the second drain electrode 9. That is, a shape of the second drain electrode 9 is not particularly limited, provided that the second drain electrode 9, as a continuous layer, covers a part of the surface of the drain electrode 5, a part of the surface of the second organic molecular layer 6b, and a part of the top surface of the organic semiconductor layer 7. The same holds for Embodiment 2. Accordingly, respective shapes of the second source electrode 8 and the second drain electrode 9 are not particularly limited in Embodiment 2.

Embodiments 1 through 4 above show such an arrangement that the first organic molecular layer 6a and the second organic molecular layer 6b are, as a continuous layer, formed as continuous layers on the source electrode 4 and the drain electrode 5, respectively. However, Embodiments 1 through 4 are not limited to this. For example, the first organic molecular layer 6a may be divided into (i) a part which, as a continuous layer, covers that side wall of the source electrode 4 which faces the drain electrode 5 and (ii) a part which, as a continuous layer, covers a part of the top surface of the source electrode 4. That is, there is no need to form the first organic molecular layer 6a so that the part which covers the side surface of the source electrode 4 and the part which covers the top surface of the source electrode 4 are connected with each other. The same holds for the second organic molecular layer 6b. That is, there is no need to form the second organic molecular layer 6b so that its part which covers that side surface of the drain electrode 5 which faces the source electrode 4 and a part which covers a part of the top surface of the drain electrode 5 are connected with each other.

Embodiments 1, 3, and 4 above show such an arrangement that the organic semiconductor layer 7 is formed so as to entirely cover the surfaces of the organic molecular layers 6. However, Embodiments 1, 3, and 4 are not always limited to this. For example, the organic semiconductor layer 7 may be formed so as to, as a continuous layer, cover (i) a part of the top surface of the source electrode 4, (ii) a part of the top surface of the drain electrode 5, (iii) at least a part of the surface of the first organic molecular layer 6a, (iv) at least a part of the surface of the second organic molecular layer 6b, (v) and at least a part of the channel section 20 between the source electrode 4 and the drain electrode 5. That is, the embodiments of the present invention encompass such an arrangement that a width of the organic semiconductor layer 7 (i.e., a width thereof along a direction orthogonal to a direction in which the source electrode 4 and the drain electrode 5 are adjacent to each other) is smaller than a width of each of the source electrode 4, the drain electrode 5, the organic molecular layers 6, and the channel section 20. Alternatively, the organic semiconductor layer 7 may be formed so as to also cover that area of a surface of each of the source electrode 4 and the drain electrode 5 in which no organic molecular layer 6 is formed. That is, the embodiments of the present invention encompass such an arrangement that the organic semiconductor layer 7 is formed so as to extend out of an area of each of the source electrode 4, the drain electrode 5, the organic molecular layers 6, and the channel section 20.

As described above, the organic semiconductor layer 7 is formed so as to, as a continuous layer, cover at least (i) a part of the top surface of the source electrode 4, (ii) a part of the top surface of the drain electrode 5, (iii) at least a part of the surface of the first organic molecular layer 6a, (iv) at least a part of the surface of the second organic molecular layer 6b, (v) and at least a part of the channel section 20 between the source electrode 4 and the drain electrode 5. The same holds for Embodiment 2. That is, the organic semiconductor layer 7 is formed so as to, as a continuous layer, cover (i) at least a part of the top surface of the first organic molecular layer 6a, (ii) at least a part of the top surface of the second organic molecular layer 6b, and (iii) at least a part of the channel section 20 between the source electrode 4 and the drain electrode 5.

Embodiments 1 through 4 above show cases where the organic thin-film transistors 100, 200, 300, and 400 are bottom contact-type ones. However, Embodiments 1 through 4 are not limited to this. That is, needless to say, top gate-type (top contact type) ones are also applicable to the embodiments. In the case of the top gate-type, first, the source electrode 4 and the drain electrode 5 are formed on the substrate 1 so as to have a space therebetween. Then, the first organic molecular layer 6a and the second organic molecular layer 6b are formed on the source electrode 4 and the drain electrode 5, respectively. Then, the organic semiconductor layer 7 is formed so as to cover the organic molecular layers 6, the source electrode 4, and the drain electrode 5, and also get into the channel section 20. The gate insulating layer 3 is formed on the organic semiconductor layer 7, and then, the gate electrode 2 is further formed on the gate insulating layer 3. In a case where a top gate-type organic thin-film transistor is manufactured according to the present invention, a basic arrangement thereof and a manufacturing method thereof do not differ from those of the organic thin-film transistor 100 of the bottom contact-type. Therefore, the following omits to describe the basic arrangement and the manufacturing method of the top gate-type organic thin-film transistor.

In a case where a bottom contact-type organic thin-film transistor is manufactured according to the present invention, it is preferable to form a self-assembled monomolecular layer as a channel interface treatment layer, in that area on the gate insulating layer 3 which corresponds to the channel section 20 between the source electrode 4 and the drain electrode 5. In a case where a top gate-type organic thin-film transistor is manufactured according to the present invention, it is preferable to form a self-assembled monomolecular layer as a channel interface treatment layer, in that area on the substrate 1 which corresponds to the channel section 20 between the source electrode 4 and the drain electrode 5. This makes it possible to significantly increase a crystal grain size of the organic semiconductor material by use of an effect of the channel interface treatment layer.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

### Summary of Embodiments

As described above, the organic thin-film transistor of the present invention further includes: a second source electrode being formed so as to, as a continuous layer, cover a part of the surface of said source electrode and a part of a top surface of said organic semiconductor layer; and a second drain electrode being formed so as to, as a continuous layer, cover a part of the surface of said drain electrode and a part of the top surface of said organic semiconductor layer, said second drain electrode being formed so that on said organic semiconductor layer, said second drain electrode is spaced from said second source electrode.

According to the arrangement, the second source electrode and the second drain electrode are formed on the organic semiconductor layer. Specifically, the second source electrode is formed so as to have a contact with the source electrode and so that the organic semiconductor layer is sandwiched between the second source electrode and the source electrode. Similarly, the second drain electrode is formed so as to have a contact with the drain electrode and so that the organic semiconductor layer is sandwiched between the second drain electrode and the drain electrode.

Under the second source electrode, crystal gains in the organic semiconductor layer have grown in size due to an effect of the organic molecular layer. Accordingly, carrier injection from the second source electrode is performed directly on such a part where the organic semiconductor layer is large in crystal grain size. That is, the carrier injection is performed from both of the source electrode and the second source electrode to the organic semiconductor layer not via the organic molecular layer.

The same holds for a drain electrode side. Under the second drain electrode, crystal gains in the organic semiconductor layer have an increased size due to an effect of the organic molecular layer. Accordingly, carrier injection from the second drain electrode to the organic semiconductor layer is performed directly via such a part where the organic semiconductor layer is in crystal grain size. That is, the carrier injection is performed from both of the drain electrode and the second drain electrode to the organic semiconductor layer not via the organic molecular layer. Thus, in the organic thin-film transistor of the present invention, the carrier injection is performed between the organic semiconductor layer and each of the source electrode, the drain electrode, the second source electrode, and the second drain electrode, not via the organic molecular layers. This significantly increases a carrier injection efficiency. This makes it possible to increase a current to be obtained from the organic thin-film transistor.

Further, the organic thin-film transistor of the present invention is arranged such that each of said first organic molecular layer and said second organic molecular layer is a self-assembled monomolecular layer.

The self-assembled monomolecular layer has stability because the organic molecular layer can be strongly joined to the electrodes due to chemical bonding. Therefore, according to the arrangement, crystal grains in the organic semiconductor layer can increase in size in the vicinity of the organic molecular layer.

Further, the organic thin-film transistor of the present invention is arranged such that a self-assembled monomolecular layer is provided in an area on said gate insulating layer which area corresponds to the gap between said source electrode and said drain electrode.

Further, the organic thin-film transistor of the present invention is arranged such that a self-assembled monomolecular layer is provided in an area on said substrate which area corresponds to the gap between said source electrode and said drain electrode.

Further, the method of the present invention for manufacturing an organic thin-film transistor further includes, after the step of forming the organic semiconductor layer, the steps of: forming a second source electrode which, as a continuous layer, covers a part of the surface of the source electrode and a part of a top surface of the organic semiconductor layer; and forming a second drain electrode which, as a continuous layer, covers a part of the surface of the drain electrode and a part of the top surface of the organic semiconductor layer, the second drain electrode being formed so that on the organic semiconductor layer, the second drain electrode is spaced from the second source electrode.

### EXAMPLES

The following describes the present invention in more detail, by showing Examples and Comparative Examples. The present invention is not limited to Examples, provided that the present invention does not go beyond its gist.

### Example 1

An n-type monocrystalline silicon substrate was employed as a substrate which also serves as a gate electrode. A thermally-oxidized film (gate insulating layer) having a thickness of 100 nm was formed on the substrate. Then, a photoresist film having an opening was formed on the thermally-oxidized film. Then, deposited into the opening by the vacuum deposition method was that metal thin film having a thickness of 60 nm which had a two-layer structure made up of a layer of gold (Au) and a layer of a gold-nickel (Ni) alloy (Au/Ni=97%/3%). Then, a liftoff process was performed in which the substrate was immersed in an N-methylpyrrolidone solvent, thereby removing the photoresist film. Thus formed are a source electrode and a drain electrode.

Then, a hexamethyldisilazane solution was dropped onto the substrate, and then the substrate was baked in an oven at 120° C. for 30 minutes. Then, the substrate was immersed in an acetone solution for 5 minutes. Then, the substrate was immersed in an isopropyl alcohol solution for 5 minutes. Then, a drying process of drying the substrate by nitrogen blowing was performed so that a channel section (i.e., a gap between the source electrode and the drain electrode) was modified with hexamethyldisilazane molecules.

Then, a metal mask which had a 50 μm×500 μm opening and was coated with fluorine was placed on the substrate so that the opening of the metal mask partially overlaps each of the channel section, the source electrode, and the drain electrode. In the presence of nitrogen, a small amount of an n-octadecanethiol solution (anhydrous ethanol solution) at a concentration of 5 mM was dropped from above the metal mask onto the substrate. After being left at rest for 10 minutes, the substrate with the metal mask thereon was rinsed with ethanol, and then immersed in an ethanol solution for 5 minutes. The series of operations from the solution dripping to the immersion were repeated three times. Finally, the substrate was dried by nitrogen blowing. Thus, a first organic molecular layer was formed which, as a continuous layer, covers a part of a surface of the source electrode, and that surface (side surface) of the source electrode which faces the channel section. Similarly, a second organic molecular layer was formed which, as a continuous layer, covers a part of a surface of the drain electrode, and that surface (side surface) of the drain electrode which faces the channel section. Thus, the substrate was modified with the organic molecular layers (first organic molecular layer and the second organic molecular layer).

Finally, an organic semiconductor layer having a thickness of 100 nm was formed from p-type pentacene at 50° C. by the vacuum deposition method, via a mask having an opening which faces an area, as a continuous layer, covering the channel section, the organic molecular layers, a part of a top surface of the source electrode, and a part of a top surface of the drain electrode. The organic thin-film transistor was thus made.

By use of a semiconductor parameter analyzer B1500 manufactured by Agilent Technologies, Inc., a current (on-state current) was measured which passed between the source electrode and the drain electrode while a drain voltage of 40 V and a gate voltage of 30 V were applied to the organic thin-film transistor thus made. The on-state current thus measured was 50 μA.

### Example 2

Example 2 was carried out in the same way as in Example 1, up to the formation of the organic semiconductor layer, and therefore is not described repeatedly herein as to the processes up to the formation of the organic semiconductor layer. After the organic molecular layers were formed, an organic semiconductor layer having a thickness of 100 nm was formed from p-type pentacene at 50° C. by the vacuum deposition method, via a mask having an opening over an area, as a continuous layer, covering a part of a top surface of the organic molecular layer formed on the source electrode, the channel section, and a top surface of the organic molecular layer formed on the drain electrode. Thus, an organic semiconductor layer was formed which was patterned so as to have no contact with source electrode and the drain electrode, and so as to cover the channel section and the organic molecular layers.

Finally, a second source electrode and a second drain electrode each of which had a thickness of 100 nm were formed by the vacuum deposition method, via a metal mask having openings corresponding respectively to (i) an area, as a continuous layer, covering a part of a surface of each of the source electrode, the first organic molecular layer, and the organic semiconductor layer, and (ii) an area, as a continuous layer, covering a part of a surface of each of the drain electrode, the second organic molecular layer, and the organic semiconductor layer. The organic thin-film transistor was thus made.

In the same way as in Example 1, a current (on-state current) was measured which passed between the source electrode and the drain electrode while a drain voltage of 40 V and a gate voltage of 30 V were applied to the organic thin-film transistor thus made. The on-state current thus measured was 55 μA.

### Example 3

Example 3 was carried out in the same way as in Example 1, up to the formation of the organic semiconductor layer, and therefore is not described repeatedly herein as to the processes up to the formation of the organic semiconductor layer. After the organic semiconductor layer was formed, a second source electrode and a second drain electrode each of which had a thickness of 100 nm were formed by the vacuum deposition method, via a metal mask having openings which were opened correspondingly to (i) an area, as a continuous layer, covering a part of a surface of each of the source electrode and the organic semiconductor layer, and (ii) an area, as a continuous layer, covering a part of a surface of each of the drain electrode and the organic semiconductor layer. The organic thin-film transistor was thus made.

In the same way as in Example 1, a current (on-state current) was measured which passed between the source electrode and the drain electrode while a drain voltage of 40 V and a gate voltage of 30 V were applied to the organic thin-film transistor thus made. The on-state current thus measured was 75 μA.

### Example 4

Example 4 was carried out in the same way as in Example 1, up to the formation of the organic semiconductor layer, and therefore is not described repeatedly herein as to the processes up to the formation of the organic semiconductor layer. After the organic semiconductor layer was formed, a second source electrode and a second drain electrode each of which had a thickness of 100 nm and was patterned so as to have a contact with a part of the surface of the organic semiconductor layer were formed by the vacuum deposition method via a metal mask. The organic thin-film transistor was thus made.

In the same way as in Example 1, a current (on-state current) was measured which passed between the source electrode and the drain electrode when a drain voltage of 40 V and a gate voltage of 30 V were applied to the organic thin-film transistor thus made. The on-state current thus measured was 65 μA.

### Example 5

Example 5 was carried out in the same way as in Example 1, up to the formation of the organic semiconductor layer, and therefore is not described repeatedly herein as to the processes up to the formation of the organic semiconductor layer. After the source electrode and the drain electrode were formed, a polyvinyl phenol solution was applied to the substrate by use of a dispenser in the presence of nitrogen. Then, the substrate was dried. Thus, the organic molecular layers were formed. A process of forming an organic semiconductor layer was performed as in Example 1. Therefore, the following omits to describe the process. The organic thin-film transistor was thus made.

In the same way as in Example 1, a current (on-state current) was measured which passed between the source electrode and the drain electrode while a drain voltage of 40 V and a gate voltage of 30 V were applied to the organic thin-film transistor thus made. The on-state current thus measured was 40 μA.

### Comparative Example 1

Comparative Example 1 was carried out in the same way as in Example 1, up to the formation of the organic semiconductor layer, and therefore is not described repeatedly herein as to the processes up to the formation of the organic semiconductor layer.

After the source electrode and the drain electrode were formed, an n-octadecanethiol solution (anhydrous ethanol solution) at a concentration of 5 mM was directly dropped onto the substrate. After being left at rest for 10 minutes, the substrate was rinsed with ethanol, and then immersed in an ethanol solution for 5 minutes. The series of operations from the solution dripping to the immersion were repeated three times. Finally, the substrate was dried by nitrogen blowing. The organic molecular layers were thus formed which cover the entire surface of each of the source electrode and the drain electrode. The process of forming the organic semiconductor layer was performed as in Example 1. Therefore, the following omits to describe the process. The organic thin-film transistor was thus made.

In the same way as in Example 1, a current (on-state current) was measured which passed between the source electrode and the drain electrode while a drain voltage of 40 V and a gate voltage of 30 V were applied to the organic thin-film transistor thus made. The on-state current thus measured was 20 μA.

TABLE 1

| | On-state Current |
|---|---|
| | (μA) |
| Example 1 | 50 |
| Example 2 | 55 |
| Example 3 | 75 |
| Example 4 | 65 |
| Example 5 | 40 |
| Comparative | 20 |
| Example 1 | |

Table 1 shows ampere values of the on-state currents obtained by applying a drain voltage of 40 V and a gate voltage of 30 V to each of the organic thin-film transistors obtained in Examples 1 through 4, and in the Comparative Example 1.

As shown in Table 1, Example 1 achieved a current flow with a higher ampere value than that of Comparative Example 1. This demonstrates that in a case where the organic semiconductor molecular layer is formed on a part of a surface each of the source electrode and the drain electrode, the carrier is injected without passing through the organic molecular layers, and as a result, a current flow with a desirably high ampere value can be obtained.

Among Examples 1, 3, and 4, Example 3 achieved a current flow with a highest ampere value, and Example 1 showed a current flow with a lowest ampere value. The results demonstrate that the organic thin-film transistor has a greater current flow in a case where each of the second source electrode and the second drain electrode has a contact with at least a part of the surface of the organic semiconductor layer. That is, it is possible to control a current of the organic thin-film transistor by changing a contact area between the organic semiconductor layer and each of the second source electrode and the second drain electrode.

Example 2 achieved a current flow with a higher ampere value than that of Example 1. This demonstrates that a current flow with a desirably high ampere value can be obtained by providing the second source electrode and the second drain electrode in such an arrangement that the organic semiconductor layer does not have a direct contact with each of the source electrode and the drain electrode.

Further, Example 5 showed a current flow with a higher ampere value than that of Example 1. The result demonstrates that a current flow with a desirably high ampere value can be obtained even in a case where the organic molecular layers are made from a material other than the self-assembled monomolecular layer.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

The present invention is applicable to display apparatuses such as an organic EL display apparatus and a liquid crystal display apparatus, and to integrated circuits etc. of electronic devices. Therefore, the present invention is widely utilized in various electronic device industries where organic thin-film transistors are used.

### REFERENCE SIGNS LIST

1 Substrate
2 Gate electrode
3 Gate insulating layer
4 Source electrode
5 Drain electrode
6 Organic molecular layer
6a First organic molecular layer
6b Second organic molecular layer
7 Organic semiconductor layer
8 Second source electrode
9 Second drain electrode
12 Photoresist film
13 Electrode material
14 Metal mask
15 Organic molecular layer material
17, 18 Crystal grain
20 Channel section
30a, 30b Conventional organic thin-film transistor
100, 200, 300, 400 Organic thin-film transistor

1. An organic thin-film transistor comprising:
a substrate;
a gate electrode;
a gate insulating layer;
a source electrode;
a drain electrode spaced from said source electrode;
a first organic molecular layer which, as a continuous layer, covers (i) a side surface of said source electrode which side surface faces said drain electrode, and (ii) a part of a top surface of said source electrode;
a second organic molecular layer which, as a continuous layer, covers (I) a side surface of said drain electrode which side surface faces said source electrode, and (II) a part of a top surface of said drain electrode; and
an organic semiconductor layer which, as a continuous layer, covers at least (i) a part of the top surface of said source electrode, (ii) a part of the top surface of said drain electrode, (iii) at least a part of a surface of said first organic molecular layer, (iv) at least a part of a surface of said second organic molecular layer, and (v) at least a part of a gap between said source electrode and said drain electrode.

2. The organic thin-film transistor as set forth in claim 1, further comprising:
a second source electrode being formed so as to, as a continuous layer, cover a part of the surface of said source electrode and a part of a top surface of said organic semiconductor layer; and
a second drain electrode being formed so as to, as a continuous layer, cover a part of the surface of said drain electrode and a part of the top surface of said organic semiconductor layer, said second drain electrode being formed so that on said organic semiconductor layer, said second drain electrode is spaced from said second source electrode.

3. An organic thin-film transistor comprising:
a substrate;
a gate electrode;
a gate insulating layer;
a source electrode;
a drain electrode spaced from said source electrode;
a first organic molecular layer which, as a continuous layer, covers (i) a side surface of said source electrode which side surface faces said drain electrode, and (ii) a part of a top surface of said source electrode;
a second organic molecular layer which, as a continuous layer, covers (I) a side surface of said drain electrode which side surface faces said source electrode, and (II) a part of a top surface of said drain electrode;
an organic semiconductor layer which, as a continuous layer, covers at least a part of a surface of said first organic molecular layer, at least a part of a surface of said second organic molecular layer, and at least a part of a gap between said source electrode and said drain electrode;
a second source electrode being formed so as to, as a continuous layer, cover a part of the surface of said source electrode, a part of the surface of said first organic molecular layer, and a part of a top surface of said organic semiconductor layer; and
a second drain electrode being formed so as to, as a continuous layer, cover a part of the surface of said drain electrode, a part of the surface of said second organic molecular layer, and a part of the top surface of said organic semiconductor layer, said second drain electrode being formed so that on said organic semiconductor layer, said second drain electrode is spaced from said second source electrode.

4. The organic thin-film transistor as set forth in claim 1, wherein:
each of said first organic molecular layer and said second organic molecular layer is a self-assembled monomolecular layer.

5. The organic thin-film transistor as set forth in claim 1, wherein:
said gate electrode is provided on said substrate;
said gate insulating layer is provided on said gate electrode; and
said source electrode and said drain electrode are provided on said gate insulating layer.

6. The organic thin-film transistor as set forth in claim 1, wherein:
said source electrode and said drain electrode are provided on said substrate;
said gate insulating layer is provided on said organic semiconductor layer; and
said gate electrode are provided on said gate insulating layer.

7. The organic thin-film transistor as set forth in claim 5, wherein:
a self-assembled monomolecular layer is provided in an area on said gate insulating layer which area corresponds to the gap between said source electrode and said drain electrode.

8. The organic thin-film transistor as set forth in claim 6, wherein:
a self-assembled monomolecular layer is provided in an area on said substrate which area corresponds to the gap between said source electrode and said drain electrode.

9. A method for manufacturing an organic thin-film transistor, comprising the steps of:
forming a gate electrode;
forming a gate insulating layer;
forming a source electrode and a drain electrode so that the source electrode and the drain electrode are spaced from each other;
forming a first organic molecular layer which, as a continuous layer, covers (i) a side surface of the source electrode which side surface faces the drain electrode, and (ii) a part of a top surface of the source electrode;
forming a second organic molecular layer which, as a continuous layer, covers (I) a side surface of the drain electrode which side surface faces the source electrode, and (II) a part of a top surface of the drain electrode; and
forming an organic semiconductor layer which, as a continuous layer, covers at least (i) a part of the top surface of the source electrode, (ii) a part of the top surface of the drain electrode, (iii) at least a part of a surface of the first organic molecular layer, (iv) at least a part of a surface of the second organic molecular layer, and (v) at least a part of a gap between the source electrode and the drain electrode.

10. The method as set forth in claim 9, further comprising, after the step of forming the organic semiconductor layer, the steps of:
forming a second source electrode which, as a continuous layer, covers a part of the surface of the source electrode and a part of a top surface of the organic semiconductor layer; and
forming a second drain electrode which, as a continuous layer, covers a part of the surface of the drain electrode and a part of the top surface of the organic semiconductor layer, the second drain electrode being formed so that on the organic semiconductor layer, the second drain electrode is spaced from the second source electrode.

11. A method for manufacturing an organic thin-film transistor, comprising the steps of:
forming a gate electrode;
forming a gate insulating layer;
forming a source electrode and a drain electrode so that the source electrode and the drain electrode are spaced from each other;
forming a first organic molecular layer which, as a continuous layer, covers (i) a side surface of the source electrode which side surface faces the drain electrode, and (ii) a part of a top surface of the source electrode;
forming a second organic molecular layer which, as a continuous layer, covers (I) a side surface of the drain electrode which side surface faces the source electrode, and (II) a part of a top surface of the drain electrode;
forming an organic semiconductor layer which, as a continuous layer, covers at least a part of a top surface of the first organic molecular layer, at least a part of a top surface of the second organic molecular layer, and at least a part of a gap between the source electrode and the drain electrode;
forming a second source electrode which, as a continuous layer, covers a part of the surface of the source electrode, a part of the surface of the first organic molecular layer, and a part of a top surface of the organic semiconductor layer; and
forming a second drain electrode which, as a continuous layer, covers a part of the surface of the drain electrode, a part of the surface of the second organic molecular layer, and a part of the top surface of the organic semiconductor layer, the second drain electrode being formed so that on the organic semiconductor layer, the second drain electrode is spaced from the second source electrode.

12. The method as set forth in claim 9, wherein:
in the step of forming the gate electrode, the gate electrode is formed on the substrate;
in the step of forming the gate insulating layer, the gate insulating layer is formed on the gate electrode; and
in the step of forming the source electrode and the drain electrode, the source electrode and the drain electrode are formed on the gate insulating layer.

13. The method as set forth in claim 9, wherein:
in the step of forming the source electrode and the drain electrode, the source electrode and the drain electrode are formed on the substrate;
in the step of forming the gate insulating layer, the gate insulating layer is formed on the organic semiconductor layer; and
in the step of forming the gate electrode, the gate electrode is formed on the gate insulating layer.
